(19) United States
(12) Patent Application Publication
(10) Pub. No.: US 2010/0136769 A1
(43) Pub. Date: Jun. 3, 2010

(54) GERMANIUM-BASED POLYMERS AND PRODUCTS FORMED FROM GERMANIUM-BASED POLYMERS

(76) Inventors: MAJID KESHAVARZ, Pleasanton, CA (US); Guojun Liu, Bloomington, MN (US)

Correspondence Address: COOLEY GODWARD KRONISH LLP;ATTN: Patent Group, Suite 1100, 777 - 6th Street, NW, Washington, DC, 20001, US

(21) Appl. No.: 11/614,934

(22) Filed: Dec. 21, 2006

Related U.S. Application Data
(63) Continuation of application No. 11/412,306, filed on Apr. 26, 2006, now abandoned.
(60) Provisional application No. 60/676,098, filed on Apr. 28, 2005.

(51) Int. Cl. H01L 21/20; C08G 79/00

(52) U.S. Cl. 438/478; 528/9; 257/E21.09; 977/774; 977/840

(57) ABSTRACT

Germanium-based polymers are described. In one embodiment, a germanium-based polymer includes a structure given by the formula:

[GeR]ₙ,

wherein n is a non-negative integer that is at least one, and R is selected from a wide variety of groups, such as alkyl groups, alkenyl groups, alkynyl groups, aryl groups, iminyl groups, and so forth. Also described are methods of forming germanium-based polymers, methods of forming nanoparticles from germanium-based polymers, methods of forming nanostructured materials from germanium-based polymers, nanoparticles formed from germanium-based polymers, nanostructured materials formed from germanium-based polymers, and devices formed from germanium-based polymers.

### CROSS-REFERENCE TO RELATED APPLICATION

This application is a continuation of U.S. patent application Ser. No. 11/412,306, filed on Apr. 26, 2006 which claims the benefit and priority to Provisional Application Ser. No. 60/676,098, filed on Apr. 28, 2005, the disclosure of which is incorporated herein by reference in its entirety.

### FIELD OF THE INVENTION

The invention relates generally to polymers. More particularly, the invention relates to germanium-based polymers and products formed from such germanium-based polymers, such as coatings, clusters, nanoparticles, and nanostructured materials.

### BACKGROUND OF THE INVENTION

Over the past several years, there has been an increasing interest in exploiting the extraordinary properties associated with quantum dots. As a result of quantum confinement effects, properties of quantum dots can differ from corresponding bulk values. These quantum confinement effects can arise from confinement of electrons and holes along three dimensions. For example, quantum confinement effects can lead to an increase in bandgap energy as the size of the quantum dots is decreased. Consequently, as the size of the quantum dots is decreased, light emitted by the quantum dots can be shifted towards higher energies or shorter wavelengths. By controlling the size of the quantum dots as well as a material forming the quantum dots, properties of the quantum dots can be tuned for a specific application.

Previous attempts at forming quantum dots have largely focused on quantum dots of direct bandgap materials, such as Group II-VI semiconductor materials. In contrast to such direct bandgap materials, Group IV semiconductor materials, such as germanium and silicon, have properties that render them more desirable for a variety of applications. However, previous attempts at forming quantum dots of Group IV semiconductor materials have generally suffered from a number of shortcomings. In particular, formation of quantum dots of germanium sometimes involved extreme conditions of temperature and pressure while producing undesirable byproducts and suffering from low yields. And, the quantum dots that were produced were generally incapable of exhibiting adequate levels of photoluminescence that can be tuned over a broad spectral range.

It is against this background that a need arose to develop the germanium-based polymers described herein.

### SUMMARY OF THE INVENTION

In one aspect, the invention relates to a method of forming nanoparticles of germanium. In one embodiment, the method includes dispersing a germanium-based polymer in a solvent to form a precursor mixture. The germanium-based polymer includes a repeat unit given by the formula: [GeR], wherein Ge is a germanium atom, and R is a substituent group that includes from 1 to 20 carbon atoms. The method also includes thermolyzing the precursor mixture to form nanoparticles of germanium having sizes in the range of 1 nm to 100 nm.

In another embodiment, the method includes providing a germanium-based polymer including a network backbone structure and substituent groups that are bonded to the network backbone structure. The network backbone structure includes germanium atoms that are bonded to one another. The method also includes heating the germanium-based polymer to remove the substituent groups, such that nanoparticles of germanium having sizes in the nm range are formed.

In another aspect, the invention relates to a method of forming a nanostructured material. In one embodiment, the method includes dissolving a polygermyne in an organic solvent to form a precursor mixture that includes from 1 percent to 50 percent by weight of the polygermyne. The method also includes applying the precursor mixture to a substrate to form a coating. The method further includes thermolyzing the coating in accordance with a time-temperature profile to form a nanostructured material having a porosity in the range of 10 percent to 90 percent.

Advantageously, germanium-based polymers according to various embodiments of the invention have a number of desirable properties such as physical, chemical, optical, and electrical properties. For example, germanium-based polymers according to some embodiments of the invention can be highly soluble in certain solvents or solvent mixtures, and can have photoluminescent and optical absorption properties that are desirable for a number of applications. Also, the germanium-based polymers can be highly electrically conductive without the need for extrinsic doping or chemical modification. Advantageously, germanium-based polymers according to some embodiments of the invention can be readily processed to form a number of products including germanium, such as coatings, clusters, nanoparticles, and nanostructured materials. In turn, these products can be used or incorporated in a number of devices, such as photovoltaic devices.

Other aspects and embodiments of the invention are also contemplated. The foregoing summary and the following detailed description are not meant to restrict the invention to any particular embodiment but are merely meant to describe some embodiments of the invention.

### BRIEF DESCRIPTION OF THE DRAWINGS

For a better understanding of the nature and objects of various embodiments of the invention, reference should be made to the following detailed description taken in conjunction with the accompanying drawings.

FIG. 1 plots crystallinity of a nanostructured material as a function of sintering temperature, according to an embodiment of the invention.

FIG. 2 plots electrical conductivity of a nanostructured material as a function of sintering temperature, according to an embodiment of the invention.

FIG. 3 plots elemental composition of a nanostructured material (as measured by Energy Dispersive Spectroscopy) as a function of sintering temperature, according to an embodiment of the invention.

FIG. 4 plots weight loss of a nanostructured material (as measured by Thermo Gravimetric Analysis) as a function of sintering temperature, according to an embodiment of the invention.

FIG. 5 illustrates current-voltage characteristics of a nanostructured material in the dark and under illumination, according to an embodiment of the invention.

FIG. 6 provides a Tauc plot for a nanostructured material, according to an embodiment of the invention.

### DETAILED DESCRIPTION

### Definitions

The following definitions apply to some of the elements described with regard to some embodiments of the invention. These definitions may likewise be expanded upon herein.

As used herein, the singular terms “a,” “an,” and “the” include plural referents unless the context clearly dictates otherwise. Thus, for example, reference to a solvent can include multiple solvents unless the context clearly dictates otherwise.

As used herein, the term “set” refers to a collection of one or more elements. Elements of a set can also be referred to as members of the set. Elements of a set can be the same or different. In some instances, elements of a set can share one or more common properties.

As used herein, the terms “optional” and “optionally” mean that the subsequently described event or circumstance may or may not occur and that the description includes instances where the event or circumstance occurs and instances in which it does not.

As used herein, the term “bond” and its grammatical variations refer to a coupling of two or more elements. In some instances, a bond can refer to a coupling of two or more atoms based on an attractive interaction, such that these atoms can form a stable structure. Examples of bonds include chemical bonds such as chemisorptive bonds, covalent bonds, ionic bonds, van der Waals bonds, and hydrogen bonds. The term “intermolecular bond” refers to a chemical bond between two or more atoms that form different molecules, while the term “intramolecular bond” refers to a chemical bond between two or more atoms that form a single molecule, such as, for example, a chemical bond between two groups of the single molecule. Typically, an intramolecular bond includes one or more covalent bonds, such as, for example, σ-bonds, π-bonds, and coordination bonds. The term “conjugated π-bond” refers to a σ-bond in which a set of electrons associated with that σ-bond are delocalized to at least some extent and can be transported to a remaining portion of a molecule. The term “conjugated σ-bond” refers to a π-bond in which a set of electrons associated with that π-bond are delocalized to at least some extent and can be transported to a remaining portion of a molecule. In some instances, a conjugated π-bond can be envisioned as a π-bond that has a π-orbital overlapping (e.g., substantially overlapping) a π-orbital of an adjacent π-bond.

As used herein, the term “group” refers to a set of atoms that form a portion of a molecule. In some instances, a group can include two or more atoms that are bonded to one another to form a portion of a molecule. A group can be monovalent or polyvalent (e.g., bivalent) to allow bonding to one or more additional groups of a molecule. For example, a monovalent group can be envisioned as a molecule with one of its hydrogen atoms removed to allow bonding to another group of a molecule. A group can be positively or negatively charged. For example, a positively charged group can be envisioned as a neutral group with one or more protons (i.e., H+) added, and a negatively charged group can be envisioned as a neutral group with one or more protons removed. Examples of groups include alkyl groups, alkenyl groups, alkynyl groups, aryl groups, iminyl groups, hydride groups, halo groups, hydroxy groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, thio groups, alkylthio groups, alkenylthio groups, alkynylthio groups, arylthio groups, cyano groups, nitro groups, amino groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups.

As used herein, the term “electron accepting group” refers to a group that has a tendency to attract an electron from another group of the same or a different molecule, while the term “electron donating group” refers to a group that has a tendency to provide an electron to another group of the same or a different molecule. For example, an electron accepting group can have a tendency to attract an electron from an electron donating group that is bonded to the electron accepting group. It should be recognized that electron accepting and electron providing characteristics of a group are relative. In particular, a group that serves as an electron accepting group in one molecule can serve as an electron donating group in another molecule. Examples of electron accepting groups include positively charged groups and groups including atoms with relatively high electronegativities, such as halo groups, hydroxy groups, cyano groups, and nitro groups. Examples of electron donating groups include negatively charged groups and groups including atoms with relatively low electronegativities, such as alkyl groups.

As used herein, the term “alkane” refers to a saturated hydrocarbon molecule. For certain applications, an alkane can include from 1 to 100 carbon atoms. The term “lower alkane” refers to an alkane that includes from 1 to 20 carbon atoms, such as from 1 to 10 carbon atoms, while the term “upper alkane” refers to an alkane that includes more than 20 carbon atoms, such as from 21 to 100 carbon atoms. The term “branched alkane” refers to an alkane that includes one or more branches, while the term “unbranched alkane” refers to an alkane that is straight-chained. The term “cycloalkane” refers to an alkane that includes one or more ring structures. The term “heteroalkane” refers to an alkane that has one or more of its carbon atoms replaced by one or more heteroatoms, such as N, Si, S, O, and P. The term “substituted alkane” refers to an alkane that has one or more of its hydrogen atoms replaced by one or more substituent groups, such as halo groups, hydroxy groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, thio groups, alkylthio groups, alkenylthio groups, alkynylthio groups, arylthio groups, cyano groups, nitro groups, amino groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups, while the term “unsubstituted alkane” refers to an alkane that lacks such substituent groups. Combinations of the above terms can be used to refer to an alkane having a combination of characteristics. For example, the term “branched lower alkane” can be used to refer to an alkane that includes from 1 to 20 carbon atoms and one or more branches. Examples of alkanes include methane, ethane, propane, cyclopropane, butane, 2-methlpropane, cyclobutane, and charged, hetero, or substituted forms thereof.

As used herein, the term “alkyl group” refers to a monovalent form of an alkane. For example, an alkyl group can be envisioned as an alkane with one of its hydrogen atoms removed to allow bonding to another group of a molecule. The term “lower alkyl group” refers to a monovalent form of a lower alkane, while the term “upper alkyl group” refers to a monovalent form of an upper alkane. The term “branched alkyl group” refers to a monovalent form of a branched alkane, while the term “unbranched alkyl group” refers to a monovalent form of an unbranched alkane. The term “cycloalkyl group” refers to a monovalent form of a cycloalkane, and the term “heteroalkyl group” refers to a monovalent form of a heteroalkane. The term “substituted alkyl group” refers to a monovalent form of a substituted alkane, while the term “unsubstituted alkyl group” refers to a monovalent form of an unsubstituted alkane. Examples of alkyl groups include methyl, ethyl, n-propyl, isopropyl, cyclopropyl, butyl, isobutyl, t-butyl, cyclobutyl, and charged, hetero, or substituted forms thereof.

As used herein, the term “alkylene group” refers to a bivalent form of an alkane. For example, an alkylene group can be envisioned as an alkane with two of its hydrogen atoms removed to allow bonding to one or more additional groups of a molecule. The term “lower alkylene group” refers to a bivalent form of a lower alkane, while the term “upper alkylene group” refers to a bivalent form of an upper alkane. The term “branched alkylene group” refers to a bivalent form of a branched alkane, while the term “unbranched alkylene group” refers to a bivalent form of an unbranched alkane. The term “cycloalkylene group” refers to a bivalent form of a cycloalkane, and the term “heteroalkylene group” refers to a bivalent form of a heteroalkane. The term “substituted alkylene group” refers to a bivalent form of a substituted alkane, while the term “unsubstituted alkylene group” refers to a bivalent form of an unsubstituted alkane. Examples of alkylene groups include methylene, ethylene, propylene, 2-methylpropylene, and charged, hetero, or substituted forms thereof.

As used herein, the term “alkene” refers to an unsaturated hydrocarbon molecule that includes one or more carbon-carbon double bonds. For certain applications, an alkene can include from 2 to 100 carbon atoms. The term “lower alkene” refers to an alkene that includes from 2 to 20 carbon atoms, such as from 2 to 10 carbon atoms, while the term “upper alkene” refers to an alkene that includes more than 20 carbon atoms, such as from 21 to 100 carbon atoms. The term “cycloalkene” refers to an alkene that includes one or more ring structures. The term “heteroalkane” refers to an alkene that has one or more of its carbon atoms replaced by one or more heteroatoms, such as N, Si, S, O, and P. The term “substituted alkene” refers to an alkene that has one or more of its hydrogen atoms replaced by one or more substituent groups, such as alkyl groups, halo groups, hydroxy groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, thio groups, alkylthio groups, alkenylthio groups, alkynylthio groups, arylthio groups, cyano groups, nitro groups, amino groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups, while the term “unsubstituted alkene” refers to an alkene that lacks such substituent groups. Combinations of the above terms can be used to refer to an alkene having a combination of characteristics. For example, the term “substituted lower alkene” can be used to refer to an alkene that includes from 1 to 20 carbon atoms and one or more substituent groups. Examples of alkenes include ethene, propene, cyclopropene, 1-butene, trans-2 butene, cis-2-butene, 1,3-butadiene, 2-methylpropene, cyclobutene, and charged, hetero, or substituted forms thereof.

As used herein, the term “alkenyl group” refers to a monovalent form of an alkene. For example, an alkenyl group can be envisioned as an alkene with one of its hydrogen atoms removed to allow bonding to another group of a molecule. The term “lower alkenyl group” refers to a monovalent form of a lower alkene, while the term “upper alkenyl group” refers to a monovalent form of an upper alkene. The term “cycloalkenyl group” refers to a monovalent form of a cycloalkene, and the term “heteroalkenyl group” refers to a monovalent form of a heteroalkene. The term “substituted alkenyl group” refers to a monovalent form of a substituted alkene, while the term “unsubstituted alkenyl group” refers to a monovalent form of an unsubstituted alkene. Examples of alkenyl groups include ethenyl, 2-propenyl (i.e., allyl), isopropenyl, cyclopropenyl, butenyl, isobutenyl, t-butenyl, cyclobutenyl, and charged, hetero, or substituted forms thereof.

As used herein, the term “alkenylene group” refers to a bivalent form of an alkene. For example, an alkenylene group can be envisioned as an alkene with two of its hydrogen atoms removed to allow bonding to one or more additional groups of a molecule. The term “lower alkenylene group” refers to a bivalent form of a lower alkene, while the term “upper alkenylene group” refers to a bivalent form of an upper alkene. The term “cycloalkenylene group” refers to a bivalent form of a cycloalkene, and the term “heteroalkenylene group” refers to a bivalent form of a heteroalkene. The term “substituted alkenylene group” refers to a bivalent form of a substituted alkene, while the term “unsubstituted alkenylene group” refers to a bivalent form of an unsubstituted alkene. Examples of alkenyl groups include ethenylene, propenylene, 2-methylpropenylene, and charged, hetero, or substituted forms thereof.

As used herein, the term “alkyne” refers to an unsaturated hydrocarbon molecule that includes one or more carbon-carbon triple bonds. In some instances, an alkyne can also include one or more carbon-carbon double bonds. For certain applications, an alkyne can include from 2 to 100 carbon atoms. The term “lower alkyne” refers to an alkyne that includes from 2 to 20 carbon atoms, such as from 2 to 10 carbon atoms, while the term “upper alkyne” refers to an alkyne that includes more than 20 carbon atoms, such as from 21 to 100 carbon atoms. The term “cycloalkyne” refers to an alkyne that includes one or more ring structures. The term “heteroalkyne” refers to an alkyne that has one or more of its carbon atoms replaced by one or more heteroatoms, such as N, Si, S, O, and P. The term “substituted alkyne” refers to an alkyne that has one or more of its hydrogen atoms replaced by one or more substituent groups, such as alkyl groups, alkenyl groups, halo groups, hydroxy groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, thio groups, alkylthio groups, alkenylthio groups, alkynylthio groups, arylthio groups, cyano groups, nitro groups, amino groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups. N-substituted arylcarbonylamino groups, silyl groups, and siloxy groups, while the term “unsubstituted alkyne” refers to an alkyne that lacks such substituent groups. Combinations of the above terms can be used to refer to an alkyne having a combination of characteristics. For example, the term “substituted lower alkyne” can be used to refer to an alkyne that includes from 1 to 20 carbon atoms and one or more substituent groups. Examples of alkenes include ethyne (i.e., acetylene), propyne, 1-butyne, 1-buten-3-yne, 1-pentyne, 2-pentyne, 3-penten-1-yne, 1-penten-4-yne, 3-methyl-1-butyne, and charged, hetero, or substituted forms thereof.

As used herein, the term “alkynyl group” refers to a monovalent form of an alkyne. For example, an alkynyl group can be envisioned as an alkyne with one of its hydrogen atoms removed to allow bonding to another group of a molecule. The term “lower alkynyl group” refers to a monovalent form of a lower alkyne, while the term “upper alkynyl group” refers to a monovalent form of an upper alkyne. The term “cycloalkynyl group” refers to a monovalent form of a cycloalkyne, and the term “heteroalkynyl group” refers to a monovalent form of a heteroalkyne. The term “substituted alkynyl group” refers to a monovalent form of a substituted alkyne, while the term “unsubstituted alkynyl group” refers to a monovalent form of an unsubstituted alkyne. Examples of alkynyl groups include ethynyl, propynyl, isopropynyl, butynyl, isobutynyl, t-butynyl, and charged, hetero, or substituted forms thereof.

As used herein, the term “alkynylene group” refers to a bivalent form of an alkyne. For example, an alkynylene group can be envisioned as an alkyne with two of its hydrogen atoms removed to allow bonding to one or more additional groups of a molecule. The term “lower alkynylene group” refers to a bivalent form of a lower alkyne, while the term “upper alkynylene group” refers to a bivalent form of an upper alkyne. The term “cycloalkynylene group” refers to a bivalent form of a cycloalkyne, and the term “heteroalkynylene group” refers to a bivalent form of a heteroalkyne. The term “substituted alkynylene group” refers to a bivalent form of a substituted alkyne, while the term “unsubstituted alkynylene group” refers to a bivalent form of an unsubstituted alkyne. Examples of alkynylene groups include ethynylene, propynylene, 1-butynylene, 1-buten-3-ynylene, and charged, hetero, or substituted forms thereof.

As used herein, the term “arene” refers to an aromatic hydrocarbon molecule. For certain applications, an arene can include from 5 to 100 carbon atoms. The term “lower arene” refers to an arene that includes from 5 to 20 carbon atoms, such as from 5 to 14 carbon atoms, while the term “upper arene” refers to an arene that includes more than 20 carbon atoms, such as from 21 to 100 carbon atoms. The term “monocyclic arene” refers to an arene that includes a single aromatic ring structure, while the term “polycyclic arene” refers to an arene that includes more than one aromatic ring structure, such as two or more aromatic ring structures that are bonded via a carbon-carbon bond or that are fused together. The term “heteroarene” refers to an arene that has one or more of its carbon atoms replaced by one or more heteroatoms, such as N, Si, S, O, and P. The term “substituted arene” refers to an arene that has one or more of its hydrogen atoms replaced by one or more substituent groups, such as alkyl groups, alkenyl groups, alkynyl groups, iminyl groups, halo groups, hydroxy groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, thio groups, alkylthio groups, alkenylthio groups, alkynylthio groups, arylthio groups, cyano groups, nitro groups, amino groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups, while the term “unsubstituted arene” refers to an arene that lacks such substituent groups. Combinations of the above terms can be used to refer to an arene having a combination of characteristics. For example, the term “monocyclic lower alkene” can be used to refer to an arene that includes from 5 to 20 carbon atoms and a single aromatic ring structure. Examples of arenes include benzene, biphenyl, naphthalene, anthracene, pyridine, pyridazine, pyrimidine, pyrazine, quinoline, isoquinoline, and charged, hetero, or substituted forms thereof.

As used herein, the term “aryl group” refers to a monovalent form of an arene. For example, an aryl group can be envisioned as an arene with one of its hydrogen atoms removed to allow bonding to another group of a molecule. The term “lower aryl group” refers to a monovalent form of a lower arene, while the term “upper aryl group” refers to a monovalent form of an upper arene. The term “monocyclic aryl group” refers to a monovalent form of a monocyclic arene, while the term “polycyclic aryl group” refers to a monovalent form of a polycyclic arene. The term “heteroaryl group” refers to a monovalent form of a heteroarene. The term “substituted aryl group” refers to a monovalent form of a substituted arene, while the term “unsubstituted arene group” refers to a monovalent form of an unsubstituted arene. Examples of aryl groups include phenyl, biphenylyl, naphthyl, pyridinyl, pyridazinyl, pyrimidinyl, pyrazinyl, quinolyl, isoquinolyl, and charged, hetero, or substituted forms thereof.

As used herein, the term “imine” refers to a molecule that includes one or more carbon-nitrogen double bonds. For certain applications, an imine can include from 1 to 100 carbon atoms. The term “lower imine” refers to an imine that includes from 1 to 20 carbon atoms, such as from 1 to 10 carbon atoms, while the term “upper imine” refers to an imine that includes more than 20 carbon atoms, such as from 21 to 100 carbon atoms. The term “cycloimine” refers to an imine that includes one or more ring structures. The term “heteroimine” refers to an imine that has one or more of its carbon atoms replaced by one or more heteroatoms, such as N, Si, S, O, and P. The term “substituted imine” refers to an imine that has one or more of its hydrogen atoms replaced by one or more substituent groups, such as alkyl groups, alkenyl groups, alkynyl groups, halo groups, hydroxy groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, thio groups, alkylthio groups, alkenylthio groups, alkynylthio groups, arylthio groups, cyano groups, nitro groups, amino groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups, while the term “unsubstituted imine” refers to an imine that lacks such substituent groups. Combinations of the above terms can be used to refer to an imine having a combination of characteristics. For example, the term “substituted lower imine” can be used to refer to an imine that includes from 1 to 20 carbon atoms and one or more substituent groups. Examples of imines include R⁽¹⁾CHNR⁽²⁾, where R⁽¹⁾ and R⁽²⁾ are independently selected from hydride groups, alkyl groups, alkenyl groups, and alkynyl groups.

As used herein, the term “iminyl group” refers to a monovalent form of an imine. For example, an iminyl group can be envisioned as an imine with one of its hydrogen atoms removed to allow bonding to another group of a molecule. The term “lower iminyl group” refers to a monovalent form of a lower imine, while the term “upper iminyl group” refers to a monovalent form of an upper imine. The term “cycloiminyl group” refers to a monovalent form of a cycloimine, and the term “heteroiminyl group” refers to a monovalent form of a heteroimine. The term “substituted iminyl group” refers to a monovalent form of a substituted imine, while the term “unsubstituted iminyl group” refers to a monovalent form of an unsubstituted imine. Examples of iminyl groups include —R⁽³⁾CH═NR⁽⁴⁾, R⁽⁵⁾CH═NR⁽⁶⁾—, CH═NR⁽⁷⁾, and R⁽⁸⁾CH═N—, where R⁽³⁾ and R⁽⁶⁾ are independently selected from alkylene groups, alkenylene groups, and alkynylene groups, and R⁽⁴⁾, R⁽⁵⁾, R⁽⁷⁾, and R⁽⁸⁾ are independently selected from hydride groups, alkyl groups, alkenyl groups, and alkynyl groups.

As used herein, the term “alcohol” refers to a molecule that includes one or more hydroxy groups. For certain applications, an alcohol can also be referred to as a substituted molecule, such as a substituted alkane, that has one or more of its hydrogen atoms replaced by one or more hydroxy groups. Examples of alcohols include R⁽⁹⁾OH, where R⁽⁹⁾ is selected from alkyl groups, alkenyl groups, alkynyl groups, and aryl groups.

As used herein, the term “amine” refers to a molecule that includes one or more carbon-nitrogen single bonds. For certain applications, an amine can also be referred to as a heteromolecule, such as a heteroalkane, that has one or more of its carbon atoms replaced by one or more nitrogen atoms. Examples of amines include NR⁽¹⁰⁾R⁽¹¹⁾R⁽¹²⁾, where R⁽¹⁰⁾, R⁽¹¹⁾, and R⁽¹²⁾ are selected from hydride groups, alkyl groups, alkenyl groups, alkynyl groups, and aryl groups, and at least one of R⁽¹⁰⁾, R⁽¹¹⁾, and R⁽¹²⁾ is not a hydride group.

As used herein, the term “thiol” refers to a molecule that includes one or more thio groups. For certain applications, a thiol can also be referred to as a substituted molecule, such as a substituted alkane, that has one or more of its hydrogen atoms replaced by one or more thio groups. Examples of thiols include R⁽¹³⁾SH, where R⁽¹³⁾ is selected from alkyl groups, alkenyl groups, alkynyl groups, and aryl groups.

As used herein, the term “ether” refers to a molecule that includes one or more groups of the form: —O—. For certain applications, an ether can also be referred to as a heteromolecule, such as a heteroalkane, that has one or more of its carbon atoms replaced by one or more oxygen atoms. Examples of ethers include R⁽¹⁴⁾OR⁽¹⁵⁾, where R⁽¹⁴⁾ and R⁽¹⁵⁾ are independently selected from alkyl groups, alkenyl groups, alkynyl groups, and aryl groups.

As used herein, the term “hydride group” refers to —OH.

As used herein, the term “halo group” refers to —X, where X is a halogen atom. Examples of halo groups include fluoro, chloro, bromo, and iode.

As used herein, the term “hydroxy group” refers to —OH.

As used herein, the term “alkoxy group” refers to —OR⁽¹⁶⁾, where R⁽¹⁶⁾ is an alkyl group.

As used herein, the term “alkenoxy group” refers to —OR⁽¹⁷⁾, where R⁽¹⁷⁾ is an alkenyl group.

As used herein, the term “alkynoxy group” refers to —OR⁽¹⁸⁾, where R⁽¹⁸⁾ is an alkynyl group.

As used herein, the term “aryloxy group” refers to —OR⁽¹⁹⁾, where R⁽¹⁹⁾ is an aryl group.

As used herein, the term “carboxy group” refers to —COOH.

As used herein, the term “alkylcarbonyloxy group” refers to R⁽²⁰⁾COO—, where) R⁽²⁰⁾ is an alkyl group.

As used herein, the term “alkenylcarbonyloxy group” refers to R⁽²¹⁾COO—, where R⁽²¹⁾ is an alkenyl group.

As used herein, the term “alkynylcarbonyloxy group” refers to R⁽²²⁾COO—, where R⁽²²⁾ is an alkynyl group.

As used herein, the term “arylcarbonyloxy group” refers to R⁽²³⁾COO—, where R⁽²³⁾ is an aryl group.

As used herein, the term “thio group” refers to —SH.

As used herein, the term “alkylthio group” refers to —SR⁽²⁴⁾, where R⁽²⁴⁾ is an alkyl group.

As used herein, the term “alkenylthio group” refers to —SR⁽²⁵⁾, where R⁽²⁵⁾ is an alkenyl group.

As used herein, the term “alkynylthio group” refers to —SR⁽²⁶⁾, where R⁽²⁶⁾ is an alkynyl group.

As used herein, the term “arylthio group” refers to —SR⁽²⁷⁾, where R⁽²⁷⁾ is an aryl group.

As used herein, the term “cyano group” refers to —CN.

As used herein, the term “nitro group” refers to —NO₂.

As used herein, the term “amino group” refers to —NH₂.

As used herein, the term “N-substituted amino group” refers to an amino group that has one or more of its hydrogen atoms replaced by one or more substituent groups. Examples of N-substituted amino groups include —NR⁽²⁸⁾R⁽²⁹⁾, where R⁽²⁸⁾ and R⁽²⁹⁾ are selected from hydride groups, alkyl groups, alkenyl groups, alkynyl groups, and aryl groups, and at least one of R⁽²⁸⁾ and R⁽²⁹⁾ is not a hydride group.

As used herein, the term “alkylcarbonylamino group” refers to —NHCOR⁽³⁰⁾, where R⁽³⁰⁾ is an alkyl group.

As used herein, the term “N-substituted alkylcarbonylamino group” refers to an alkylcarbonylamino group that has its hydrogen atom, which is bonded to its nitrogen atom, replaced by a substituent group. Examples of N-substituted alkylcarbonylamino groups include —NR⁽³¹⁾COR⁽³²⁾, where R⁽³¹⁾ is selected from alkyl groups, alkenyl groups, alkynyl groups, and aryl groups, and R⁽³²⁾ is an alkyl group.

As used herein, the term “alkenylcarbonylamino group” refers to —NHCOR⁽³³⁾, where R⁽³³⁾ is an alkenyl group.

As used herein, the term “N-substituted alkenylcarbonylamino group” refers to an alkenylcarbonylamino group that has its hydrogen atom, which is bonded to its nitrogen atom, replaced by a substituent group. Examples of N-substituted alkenylcarbonylamino groups include —NR⁽³⁴⁾COR⁽³⁵⁾, where R⁽³⁴⁾ is selected from alkyl groups, alkenyl groups, alkynyl groups, and aryl groups, and R⁽³⁵⁾ is an alkenyl group.

As used herein, the term “alkynylcarbonylamino group” refers to —NHCOR⁽³⁶⁾, where R⁽³⁶⁾ is an alkynyl group.

As used herein, the term “N-substituted alkynylcarbonylamino group” refers to an alkynylcarbonylamino group that has its hydrogen atom, which is bonded to its nitrogen atom, replaced by a substituent group. Examples of N-substituted alkynylcarbonylamino groups include —NR⁽³⁷⁾COR⁽³⁸⁾, where R⁽³⁷⁾ is selected from alkyl groups, alkenyl groups, alkynyl groups, and aryl groups, and R⁽³⁸⁾ is an alkynyl group.

As used herein, the term “arylcarbonylamino group” refers to —NHCOR⁽³⁹⁾, where R⁽³⁹⁾ is an aryl group.

As used herein, the term “N-substituted arylcarbonylamino group” refers to an arylcarbonylamino group that has its hydrogen atom, which is bonded to its nitrogen atom, replaced by a substituent group. Examples of N-substituted arylcarbonylamino groups include NR⁽⁴⁰⁾COR⁽⁴¹⁾, where R⁽⁴⁰⁾ is selected from alkyl groups, alkenyl groups, alkynyl groups, and aryl groups, and R⁽⁴¹⁾ is an aryl group.

As used herein, the term “silyl group” refers to —SiR⁽⁴²⁾R⁽⁴³⁾R⁽⁴⁴⁾, where R⁽⁴²⁾, R⁽⁴³⁾, and R⁽⁴⁴⁾ are independently selected from a wide variety of groups, such as hydride groups, alkyl groups, alkenyl groups, alkynyl groups, and aryl groups.

As used herein, the term “siloxy group” refers to —OSiR⁽⁴⁵⁾R⁽⁴⁶⁾R⁽⁴⁷⁾, where R⁽⁴⁵⁾, R⁽⁴⁶⁾, and R⁽⁴⁷⁾ are independently selected from a wide variety of groups, such as hydride groups, alkyl groups, alkenyl groups, alkynyl groups, and aryl groups.

As used herein, the term “amide” refers to a molecule of the form: R⁽⁴⁸⁾R⁽⁴⁹⁾NCOR⁽⁵⁰⁾, where R⁽⁴⁸⁾, R⁽⁴⁹⁾, and R⁽⁵⁰⁾ are independently selected from a wide variety of groups, such as hydride groups, alkyl groups, alkenyl groups, alkynyl groups, and aryl groups.

As used herein, the term “ketone” refers to a molecule that includes one or more groups of the form: —CO—. Examples of ethers include R⁽⁵¹⁾COR⁽⁵²⁾, where R⁽⁵¹⁾ and R⁽⁵²⁾ are independently selected from alkyl groups, alkenyl groups, alkynyl groups, and aryl groups.

As used herein, the terms “photoluminescence” and “photoluminescent” refer to the emission of light of a first wavelength (or a first range of wavelengths) by a material that has been irradiated with light of a second wavelength (or a second range of wavelengths). The first wavelength (or the first range of wavelengths) and the second wavelength (or the second range of wavelengths) can be the same or different.

As used herein, the term “photoluminescence quantum efficiency” refers to the ratio of the number of photons emitted by a material to the number of photons absorbed by the material.

As used herein, the term “defect” refers to a crystal stacking error, a trap, a vacancy, an insertion, or an impurity, such as an atomic or molecular dopant.

As used herein, the term “monolayer” refers to a single complete coating of a material with no additional material added beyond the complete coating.

As used herein, the term “photoactive material” refers to a material that can be used to produce electrical energy from light energy. While this term in the context of certain embodiments of the invention is typically used to refer to a nanostructured material, this term can also be used to refer to other photoactive materials, such as conventional photoactive materials.

As used herein, the term “nanometer range” or “nm range” refers to a size range from about 0.1 nm to about 1000 nm, such as from about 0.1 nm to about 500 nm, from about 0.1 nm to about 200 nm, from about 0.1 nm to about 100 nm, from about 1 nm to about 100 nm, from about 1 nm to about 50 nm, from about 1 nm to about 20 nm, or from about 1 nm to about 10 nm.

As used herein, the term “nanoparticle” refers to a particle that has at least one dimension in the nanometer range. A nanoparticle can have any of a number of shapes and can be formed from any of a number of materials. In some instances, a nanoparticle includes a “core” of a first material, which core can be optionally surrounded by a “shell” of a second material or by a “ligand layer.” The first material and the second material can be the same or different. Depending on the configuration of a nanoparticle, the nanoparticle can exhibit size dependent properties associated with quantum confinement. However, it is contemplated that a nanoparticle can also substantially lack size dependent properties associated with quantum confinement or can exhibit such size dependent properties to a low degree. In some instances, a set of nanoparticles can be referred to as being “substantially defect free.” When referring to a set of nanoparticles as being substantially defect free, it is contemplated that there is fewer than 1 defect per nanoparticle, such as less than 1 defect per 1000 nanoparticles, less than 1 defect per 10⁶ nanoparticles, or less than 1 defect per 10⁹ nanoparticles. Typically, a smaller number of defects within a nanoparticle translates into an increased photoluminescence quantum efficiency. In some instances, a nanoparticle that is substantially defect free can have a photoluminescence quantum efficiency that is greater than 6 percent, such as at least 10 percent, at least 20 percent, at least 30 percent, at least 40 percent, or at least 50 percent. Examples of nanoparticles include quantum dots, quantum wells, and quantum wires.

As used herein, the term “size” refers to a characteristic physical dimension. In the case of a nanoparticle that exhibits size dependent properties associated with quantum confinement, a size of the nanoparticle can refer to a quantum-confined physical dimension of the nanoparticle. For example, in the case of a nanoparticle that is substantially spherical, a size of the nanoparticle corresponds to a diameter of the nanoparticle. In the case of a nanoparticle that is substantially rod-shaped with a substantially circular cross-section, a size of the nanoparticle corresponds to a diameter of the cross-section of the nanoparticle. When referring to a set of nanoparticles as being of a particular size, it is contemplated that the set of nanoparticles can have a distribution of sizes around the specified size. Thus, as used herein, a size of a set of nanoparticles can refer to a typical size associated with a distribution of sizes, such as a mean size, a median size, or a peak size.

As used herein, the term “monodisperse” refers to a set of nanoparticles such that at least about 60% of the set of nanoparticles, such as at least about 75% to about 90%, falls within a specified size range. In some instances, a set of monodispersed nanoparticles can have sizes exhibiting a root-mean-square (“rms”) deviation of less than about 20%, such as less than about 10% or less than about 5%.

As used herein, the term “quantum dot” refers to a nanoparticle that exhibits size dependent properties, such as chemical, optical, and electrical properties, substantially along three orthogonal dimensions. A quantum dot can have any of a number of shapes, such as spherical, tetrahedral, tripodal, disk-shaped, pyramid-shaped, box-shaped, cube-shaped, and a number of other geometric and non-geometric shapes. A quantum dot that includes a core surrounded by a shell can be referred to as a “core-shell quantum dot.” Examples of quantum dots include nanospheres, nanotetrapods, nanotripods, nanomultipods, and nanoboxes.

As used herein, the term “quantum well” refers to a nanoparticle that exhibits size dependent properties, such as chemical, optical, and electrical properties, substantially along at most a single dimension. An example of a quantum well is a nanoplate.

As used herein, the term “quantum wire” refers to a nanoparticle that exhibits size dependent properties, such as chemical, optical, and electrical properties, substantially along at most two orthogonal dimensions. Examples of quantum wires include nanorods, nanotubes, and nanocolumns.

As used herein, the term “core” refers to an inner portion of a nanoparticle. A core can substantially include a single homogeneous monoatomic or polyatomic material. A core can be crystalline, polycrystalline, or amorphous and can optionally include dopants. A core can be substantially defect free or can contain a range of defect densities. While a core sometimes can be referred to as “crystalline” or “substantially crystalline,” it is contemplated that the surface of the core can be polycrystalline or amorphous and that this polycrystalline or amorphous surface can extend a measurable depth within the core to form a “core-surface region.” The potentially non-crystalline nature of the core-surface region does not change what is referred to herein as a substantially crystalline core. The core-surface region can sometimes include defects. In some instances, the core-surface region can range in depth from about one to about five atomic-layers and can be substantially homogeneous, substantially inhomogeneous, or continuously varying as a function of position within the core-surface region.

As used herein, the term “shell” refers to an outer portion of a nanoparticle. A shell can include a layer of a material that covers at least a portion of the surface of a core. An interface region can be optionally positioned between a core and a shell. A shell can substantially include a single homogeneous monoatomic or polyatomic material. A shell can be crystalline, polycrystalline, or amorphous and can optionally include dopants. A shell can be substantially defect free or can contain a range of defect densities. In some instances, a material forming a shell has a bandgap energy that is larger than that of a material forming a core. In other instances, the material forming the shell can have a bandgap energy that is smaller than that of the material forming the core. The material forming the shell can have band offsets with respect to the material forming the core, such that a conduction band of the shell can be higher or lower than that of the core, and a valence band of the shell can be higher or lower than that of the core. The material forming the shell can be optionally selected to have an atomic spacing close to that of the material forming the core. A shell can be “complete,” such that the shell substantially completely covers the surface of a core to, for example, substantially cover all surface atoms of the core. Alternatively, the shell can be “incomplete,” such that the shell partially covers the surface of the core to, for example, partially cover the surface atoms of the core. A shell can have a range of thicknesses, such as from about 0.1 nm to about 10 nm. The thickness of a shell can be defined in terms of the number of monolayers of a material forming the shell. In some instances, a shell can have a thickness from about 0 to about 10 monolayers. A non-integer number of monolayers can correspond to a state in which incomplete monolayers exist. Incomplete monolayers can be homogeneous or inhomogeneous and can form islands or clumps on the surface of a core. A shell can be uniform or nonuniform in thickness. In the case of a shell having nonuniform thickness, it is contemplated that an incomplete shell can include more than one monolayer of a material. A shell can optionally include multiple layers of one or more materials in an onion-like structure, such that each layer acts as a shell for the next-most inner layer. Between each layer there is optionally an interface region.

As used herein, the term “interface region” refers to a boundary between two or more portions of a nanoparticle. For example, an interface region can be positioned between a core and a shell or between two layers of the shell. In some instances, an interface region can exhibit an atomically discrete transition between a material forming one portion of a nanoparticle and a material forming another portion of the nanoparticle. In other instances, the interface region can be an alloy of materials forming two portions of the nanoparticle. An interface region can be lattice-matched or unmatched and can be crystalline, polycrystalline, or amorphous and can optionally include dopants. An interface region can be substantially defect free or can contain a range of defect densities. An interface region can be homogeneous or inhomogeneous and can have properties that are graded between two portions of a nanoparticle, such as to provide a gradual or continuous transition. Alternatively, the transition can be discontinuous. An interface region can have a range of thicknesses, such as from about 1 to about 5 atomic layers.

As used herein, the term “ligand layer” refers to a set of surface ligands surrounding a core of a nanoparticle. A nanoparticle including a ligand layer can also include a shell. As such, a set of surface ligands of the ligand layer can be bonded, either covalently or non-covalently, to a core, a shell, or both (e.g., in the case of an incomplete shell). A ligand layer can include a single type of surface ligand or a mixture of two or more types of surface ligands. A surface ligand can have an affinity for, or can be bonded selectively to, a core, a shell, or both, at least at one portion of the surface ligand. A surface ligand can be optionally bonded at multiple portions along the surface ligand. A surface ligand can optionally include one or more additional active groups that do not interact specifically with either a core or a shell. A surface ligand can be substantially hydrophilic, substantially hydrophobic, or substantially amphiphilic. Examples of surface ligands include groups such as alkyl groups, alkenyl groups, alkenyl groups, aryl groups, iminyl groups, hydride groups, halo groups, hydroxy groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, thio groups, alkylthio groups, alkenylthio groups, alkynylthio groups, arylthio groups, cyano groups, nitro groups, amino groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups. Additional examples of surface ligands include polymers (or monomers for a polymerization reaction), inorganic complexes, molecular tethers, nanoparticles, and extended crystalline structures. A ligand layer can have a range of thicknesses. The thickness of a ligand layer can be defined in terms of the number of monolayers of a set of surface ligands forming the ligand layer. In some instances, a ligand layer has a thickness of a single monolayer or less, such as substantially less than a single monolayer.

As used herein, the term “porosity” refers to the ratio of the non-solid volume of a material to the total volume of the material. In some instances, the non-solid volume of a material can be associated with open spaces in the material, such as in the form of pores or voids.

As used herein, the term “nano-network” refers to an arrangement or a system of nanoparticles. In some instances, a nano-network has at least one dimension in the nanometer range. Nano-networks can be distinguished from one another based on materials forming the nano-networks, configuration or morphology of the nano-networks, or both. An example of a nano-network is a set of fused or interconnected nanoparticles in which the degree of fusion or interconnection can vary over a wide range, such as from little or no fusion or interconnection to complete fusion or interconnection. Such nano-network can be interdispersed, interpenetrating, fused, interconnected, or layered with any number of other nano-networks.

### Germanium-Based Polymers

Certain embodiments of the invention relate to germanium-based polymers having a number of desirable properties, such as physical, chemical, optical, and electrical properties. For example, germanium-based polymers according to some embodiments of the invention can be highly soluble in certain solvents or solvent mixtures, and can have photoluminescent and optical absorption properties that are desirable for a number of applications. Also, the germanium-based polymers can be highly electrically conductive without the need for extrinsic doping or chemical modification. Advantageously, germanium-based polymers according to some embodiments of the invention can be readily processed to form a number of products including germanium, such as coatings, nanoparticles, and nanostructured materials. In turn, these products can be used or incorporated in a number of devices, such as photovoltaic devices, thermophotovoltaic devices, photoconductors, photodetectors, photonic devices, memory cells, sensors, lasers, displays, light emitting diodes, and lighting devices.

In general, germanium-based polymers according to some embodiments of the invention can include a number of different types of backbone structures and can include one or more types of repeat units. In particular, a germanium-based polymer can have a backbone structure that is linear or non-linear. Examples of non-linear backbone structures include branched backbone structures, such those that are star branched, comb branched, or dendritic branched, and network backbone structures. For certain applications, a germanium-based polymer desirably includes a network backbone structure with a three-dimensional configuration that is highly branched. Advantageously, such three-dimensional configuration can facilitate conversion of the germanium-based polymer to form certain products, such as nanoparticles and nanostructured materials. A germanium-based polymer can be a homopolymer that includes one type of repeat unit or a copolymer that includes two or more different types of repeat units. Different types of repeat units of a copolymer can be arranged in accordance with a statistical distribution, in a random manner, in an alternating manner, in a periodic manner, in long sequences or blocks, in a radial manner, or in some other manner. Examples of copolymers include statistical copolymers, random copolymers, alternating copolymers, periodic copolymers, block copolymers, radial copolymers, and graft copolymers. In some instances, a germanium-based polymer can be capable of crosslinking, entanglement, or hydrogen bonding in order to increase its toughness or its resistance to degradation under ambient or processing conditions.

Advantageously, properties of a germanium-based polymer can be adjusted to desired levels for a number of applications. In particular, physical, chemical, optical, and electrical properties of a germanium-based polymer can be depend on, for example, its backbone structure, its molecular weight, and its composition. As further discussed below, processing conditions and reagents used to form a germanium-based polymer can be selected to adjust its backbone structure, its molecular weight, and its composition, thus providing resultant properties that are desirable for a particular application of the germanium-based polymer. For certain applications, properties of a germanium-based polymer can be adjusted by chemically modifying the germanium-based polymer, such as by ionizing the germanium-based polymer or by functionalizing the germanium-based polymer with certain substituent groups, such as electron accepting groups, electron donating groups, or groups with conjugated π-bonds (e.g., groups based on polyenes such as polyacetylene, polythiophene, and polypyrrol). Also, properties of a germanium-based polymer can be adjusted by incorporating a set of dopants into the germanium-based polymer. Examples of dopants include boron, aluminum, antimony, erbium, and phosphorus. For example, dopants can be added in the form of reagents during formation of a germanium-based polymer. As another example, dopants can be bonded to a backbone structure or to substituent groups of a germanium-based polymer subsequent to its formation.

According to an embodiment of the invention, a germanium-based polymer is a homopolymer that includes a structure given by a formula:

[GeR]ₙ. (I)

In formula (I), [GeR] is a particular type of repeat unit of the germanium-based polymer, Ge is a germanium atom, and R is a substituent group selected from, for example, alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups. For certain applications, R can include from 1 to 20 carbon atoms. Thus, for example, R can be a lower alkyl group, a lower alkenyl group, a lower alkynyl group, a lower aryl group, or a lower iminyl group. For other applications, R can include more than 20 carbon atoms. Thus, for example, R can be an upper alkyl group, an upper alkenyl group, an upper alkynyl group, an upper aryl group, or an upper iminyl group. In formula (I), n is a non-negative integer that is at least one and represents the number of repeat units included in the germanium-based polymer and, hence, a degree of polymerization of the germanium-based polymer. For certain applications, n is at least 10, such as at least 20, at least 50, at least 100, at least 500, at least 1,000, at least 5.000, at least 10,000, at least 50,000, at least 100,000, or at least 500,000. In some instances, n can be determined as a ratio of a molecular weight of the germanium-based polymer and a sum of atomic weights of Ge and R.

The germanium-based polymer given by formula (I), which can sometimes be referred to as a polygermyne, includes a network backbone structure including a number of backbone atoms that are bonded to one another in a three-dimensional configuration that can be highly branched. In particular, the backbone structure includes germanium atoms that are bonded to one another in a tetrahedral configuration with sp³ hybridization extending over at least a portion of the network backbone structure. It is also contemplated that the backbone structure can include a set of germanium atoms that are bonded to one another in other configurations, such as a trigonal configuration with sp² hybridization. On average, each germanium atom of the network backbone structure is bonded to one substituent group and to three other germanium atoms via germanium-germanium single bonds. In some instances, a substituent group can include a set of carbon atoms and can be bonded to a germanium atom via a carbon-germanium single bond. Substituent groups of the germanium-based polymer can provide enhanced solubility, mechanical integrity, and stability to the germanium-based polymer. By proper selection of the substituent groups, solubility of the germanium-based polymer can be adjusted to match different solvents having different polarities or different degrees of hydrogen bonding. Also, the substituent groups can modify a physical dimension of the germanium-based polymer or its extent of hybridization and, thus, resulting properties of the germanium-based polymer. The substituent groups can also facilitate conversion of the germanium-based polymer to a number of products including germanium, such as coatings, clusters, nanoparticles, and nanostructured materials.

The germanium-based polymer given by formula (I) can have a number of desirable properties, such as physical, chemical, optical, and electrical properties. For example, the germanium-based polymer can have photoluminescent and optical absorption properties that are desirable for a number of applications. In some instances, the germanium-based polymer can exhibit a broad absorption of light that tails into the visible region. Without wishing to be bound by a particular theory, it is believed that photoluminescent and optical absorption properties of the germanium-based polymer depend at least partly on the degree to which sp³ hybridization extends over the network backbone structure.

Also, the germanium-based polymer can be highly electrically conductive without the need for extrinsic doping or chemical modification. Without wishing to be bound by a particular theory, it is believed that electrical conductivity of the germanium-based polymer depends at least partly on the degree to which sp^{a} hybridization extends over the network backbone structure. In particular, conjugated σ-bonds associated with germanium atoms of the network backbone structure can lead to a delocalized electron network and, hence, enhanced electrical conductivity. The conjugated σ-bonds can provide a similar function as provided by conjugated π-bonds in certain conducting polymers, such as polyacetylene, polythiophene, and polypyrrol.

In addition, the germanium-based polymer can be readily processed to form a number of products including germanium, such as coatings, nanoparticles, and nanostructured materials. In particular, the germanium-based polymer can be highly soluble in certain solvents or solvent mixtures, and can be readily coated or casted from solution. In some instances, the germanium-based polymer with a higher molecular weight can be advantageous to facilitate conversion of the germanium-based polymer into certain products including a diamond-like structure. Thus, for example, the germanium-based polymer can have a molecular weight that is greater than 12,000 daltons, such as at least 15,000 daltons, at least 20,000 daltons, at least 30,000 daltons, at least 40,000 daltons, at least 50,000 daltons, at least 100,000 daltons, at least 200,000 daltons, at least 300,000 daltons, at least 400,000 daltons, at least 500,000 daltons, or at least 1,000,000 daltons. In other instances, the germanium-based polymer can have a low to moderate molecular weight that is 12,000 daltons or less, such as from 2,000 daltons to 12,000 daltons.

According to another embodiment of the invention, a germanium-based polymer is a copolymer that includes a structure given by a formula:

[GeR]ₙ[GeR′]ₘ. (II)

In formula (II), [GeR] is a first type of repeat unit of the germanium-based polymer. [GeR′] is a second type of repeat unit of the germanium-based polymer. Ge is a germanium atom, and R and R′ are independently selected from, for example, alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups. For certain applications, R and R′ can be different, and either of, or both, R and R′ can include from 1 to 20 carbon atoms. For other applications, either of, or both, R and R′ can include more than 20 carbon atoms. In formula (II), n is a non-negative integer that is at least one and represents the number of the first type of repeat unit included in the germanium-based polymer, and m is a non-negative integer that is at least one and represents the number of the second type of repeat unit included in the germanium-based polymer. Collectively, n and m represent a degree of polymerization of the germanium-based polymer. For certain applications, either of, or both, n and m is at least 10, such as at least 20, at least 50, at least 100, at least 500, at least 1,000, at least 5,000, at least 10,000, at least 50,000, at least 100,000, or at least 500,000. For other applications, the sum of n and m is at least 10, such as at least 20, at least 50, at least 100, at least 500, at least 1,000, at least 5,000, at least 10,000, at least 50,000, at least 100,000, or at least 500,000. In some instances, n and m can be determined based on a molecular weight of the germanium-based polymer and atomic weights of Ge, R, and R′.

As discussed previously in connection with formula (I), the germanium-based polymer given by formula (II) includes a network backbone structure including a number of backbone atoms that are bonded to one another in a three-dimensional configuration that can be highly branched. In particular, the backbone structure includes germanium atoms that are bonded to one another in a tetrahedral configuration with sp³ hybridization extending over at least a portion of the network backbone structure. On average, each germanium atom of the network backbone structure is bonded to one substituent group, which can be either R or R′, and to three other germanium atoms via germanium-germanium single bonds. In some instances, a substituent group can include a set of carbon atoms and can be bonded to a germanium atom via a carbon-germanium single bond. As discussed previously in connection with formula (I), the germanium-based polymer given by formula (II) can have a number of desirable properties, such as physical, chemical, optical, and electrical properties. Advantageously, differences in R and R′ can provide additional benefits to the germanium-based polymer as well as to products formed therefrom.

According to another embodiment of the invention, a germanium-based polymer is a copolymer that includes a structure given by a formula:

[GeR]ₙ[Ge]ₘ. (III)

In formula (III), [GeR] is a first type of repeat unit of the germanium-based polymer, [Ge] is a second type of repeat unit of the germanium-based polymer, Ge is a germanium atom, and R is selected from, for example, alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups. For certain applications, R can include from 1 to 20 carbon atoms. For other applications. R can include more than 20 carbon atoms. In formula (III), n is a non-negative integer that is at least one and represents the number of the first type of repeat unit included in the germanium-based polymer, and m is a non-negative integer that is at least one and represents the number of the second type of repeat unit included in the germanium-based polymer. Collectively, n and m represent a degree of polymerization of the germanium-based polymer. For certain applications, either of, or both, n and m is at least 10, such as at least 20, at least 50, at least 100, at least 500, at least 1,000, at least 5,000, at least 10,000, at least 50,000, at least 100,000, or at least 500,000. For other applications, the sum of n and m is at least 10, such as at least 20, at least 50, at least 100, at least 500, at least 1,000, at least 5,000, at least 10,000, at least 50,000, at least 100,000, or at least 500,000. In some instances, n and m can be determined based on a molecular weight of the germanium-based polymer and atomic weights of Ge, R, and R′.

As discussed previously in connection with formula (I), the germanium-based polymer given by formula (III) includes a network backbone structure including a number of backbone atoms that are bonded to one another in a three-dimensional configuration that can be highly branched. In particular, the backbone structure includes germanium atoms that are bonded to one another in a tetrahedral configuration with sp^{a} hybridization extending over at least a portion of the network backbone structure. On average, a first type of germanium atom of the network backbone structure is bonded to one substituent group and to three other germanium atoms via germanium-germanium single bonds, while a second type of germanium atom of the network backbone structure is bonded to four other germanium atoms via germanium-germanium single bonds. A germanium atom of the second type can sometimes be referred to as a neo-germanium atom. In some instances, a substituent group can include a set of carbon atoms and can be bonded to a germanium atom via a carbon-germanium single bond. As discussed previously in connection with formula (I), the germanium-based polymer given by formula (III) can have a number of desirable properties, such as physical, chemical, optical, and electrical properties. Advantageously, the germanium-based polymer given by formula (III) can include a higher proportion of germanium atoms with respect to substituent groups, and can provide additional benefits to the germanium-based polymer as well as to products formed therefrom.

According to another embodiment of the invention, a germanium-based polymer is a copolymer that includes a structure given by a formula:

[GeR]ₙ[GeR′R″]ₘ. (IV)

In formula (IV), [GeR] is a first type of repeat unit of the germanium-based polymer, [GeR′R″] is a second type of repeat unit of the germanium-based polymer, Ge is a germanium atom, and R, R′, and R″ are independently selected from, for example, alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups. R, R′, and R″ can be the same or can be different, and R, R′, and R″ can each include from 1 to 20 carbon atoms. For other applications, at least one of R, R′, and R″ can include more than 20 carbon atoms. In formula (IV), n is a non-negative integer that is at least one and represents the number of the first type of repeat unit included in the germanium-based polymer, and m is a non-negative integer that is at least one and represents the number of the second type of repeat unit included in the germanium-based polymer. Collectively, n and m represent a degree of polymerization of the germanium-based polymer. For certain applications, either of, or both, n and m is at least 10, such as at least 20, at least 50, at least 100, at least 500, at least 1,000, at least 5,000, at least 10,000, at least 50,000, at least 100,000, or at least 500,000. For other applications, the sum of n and m is at least 10, such as at least 20, at least 50, at least 100, at least 500, at least 1,000, at least 5,000, at least 10,000, at least 50,000, at least 100,000, or at least 500,000. In some instances, n and m can be determined based on a molecular weight of the germanium-based polymer and atomic weights of Ge, R, R′, and R″.

As discussed previously in connection with formula (I), the germanium-based polymer given by formula (IV) includes a network backbone structure including a number of backbone atoms that are bonded to one another in a three-dimensional configuration that can be highly branched. In particular, the backbone structure includes germanium atoms that are bonded to one another in a tetrahedral configuration with sp³ hybridization extending over at least a portion of the network backbone structure. On average, a first type of germanium atom of the network backbone structure is bonded to one substituent group and to three other germanium atoms via germanium-germanium single bonds, while a second type of germanium atom of the network backbone structure is bonded to two substituent groups and to two other germanium atoms via germanium-germanium single bonds. In some instances, a substituent group can include a set of carbon atoms and can be bonded to a germanium atom via a carbon-germanium single bond. As discussed previously in connection with formula (I), the germanium-based polymer given by formula (IV) can have a number of desirable properties, such as physical, chemical, optical, and electrical properties. Advantageously, differences in R, R′, and R″ can provide additional benefits to the germanium-based polymer as well as to products formed therefrom.

According to another embodiment of the invention, a germanium-based polymer is a copolymer that includes a structure given by a formula:

[Ge]ₙ[GeRR′]ₘ. (V)

In formula (V), [Ge] is a first type of repeat unit of the germanium-based polymer, [GeRR′] is a second type of repeat unit of the germanium-based polymer, Ge is a germanium atom, and R and R′ are independently selected from, for example, alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups. R and R′ can be the same or can be different, and either of, or both, R and R′ can include from 1 to 20 carbon atoms. For other applications, either of, or both, R and R′ can include more than 20 carbon atoms. In formula (V), n is a non-negative integer that is at least one and represents the number of the first type of repeat unit included in the germanium-based polymer, and m is a non-negative integer that is at least one and represents the number of the second type of repeat unit included in the germanium-based polymer. Collectively, n and m represent a degree of polymerization of the germanium-based polymer. For certain applications, either of, or both, n and m is at least 10, such as at least 20, at least 50, at least 100, at least 500, at least 1,000, at least 5,000, at least 10,000, at least 50,000, at least 100,000, or at least 500,000. For other applications, the sum of n and m is at least 10, such as at least 20, at least 50, at least 100, at least 500, at least 1,000, at least 5,000, at least 10,000, at least 50,000, at least 100,000, or at least 500,000. In some instances, n and m can be determined based on a molecular weight of the germanium-based polymer and atomic weights of Ge, R, and R′.

As discussed previously in connection with formula (I), the germanium-based polymer given by formula (V) includes a network backbone structure including a number of backbone atoms that are bonded to one another in a three-dimensional configuration that can be highly branched. In particular, the backbone structure includes germanium atoms that are bonded to one another in a tetrahedral configuration with sp^{a} hybridization extending over at least a portion of the network backbone structure. On average, a first type of germanium atom of the network backbone structure is bonded to four other germanium atoms via germanium-germanium single bonds, while a second type of germanium atom of the network backbone structure is bonded to two substituent groups and to two other germanium atoms via germanium-germanium single bonds. A germanium atom of the first type can sometimes be referred to as a neo-germanium atom. In some instances, a substituent group can include a set of carbon atoms and can be bonded to a germanium atom via a carbon-germanium single bond. As discussed previously in connection with formula (I), the germanium-based polymer given by formula (V) can have a number of desirable properties, such as physical, chemical, optical, and electrical properties. Advantageously, the germanium-based polymer given by formula (V) can include a higher proportion of germanium atoms with respect to substituent groups, and can provide additional benefits to the germanium-based polymer as well as to products formed therefrom.

Other types of germanium-based polymers are also contemplated. In particular, the germanium-based polymers given by formulas (I) through (V) can be end-capped so as to functionalize end or terminal sites of the germanium-based polymers. Thus, for example, the germanium-based polymer given by formula (I) can be end-capped so as to be given by a formula [GeR]ₙ[R′]ₒ, where R′ is substituent group at an end or terminal site of the germanium-based polymer and is independently selected from, for example, alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups. N-substituted alkylcarbonylamino groups, alkenylcarbonylamino groups, N-substituted alkenylcarbonylamino groups, alkynylcarbonylamino groups. N-substituted alkynylcarbonylamino groups, arylcarbonylamino groups, N-substituted arylcarbonylamino groups, silyl groups, and siloxy groups. Here, o is a non-negative integer that is at least one and represents the number of substituent groups at end or terminal sites of the germanium-based polymer and, hence, a degree of end-capping of the germanium-based polymer.

Also, the germanium-based polymers given by formulas (I) through (V) can include a set of dopants, such that products formed from the germanium-based polymers can be n-doped or p-doped. In general, the set of dopants can include one type of dopant or different types of dopants. Thus, for example, the germanium-based polymer given by formula (II) can include a set of dopants so as to be given by a formula [GeR]ₙ[GeR′]ₘ[dopant]ₒ, where the dopant is selected from, for example, boron, aluminum, antimony, erbium, and phosphorus. Here, o is a non-negative integer that is at least one and represents the number of dopants included in the germanium-based polymer and, hence, a degree of doping of the germanium-based polymer.

Also, the germanium-based polymers given by formulas (II) through (V) can include one or more additional types of repeats units. Thus, for example, the germanium-based polymer given by formula (III) can include a third type of repeat unit, such as [GeR′R″], where R′ and R″ are substituent groups independently selected from, for example, alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups. N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups.

Also, according to a further embodiment of the invention, a germanium-based polymer is a homopolymer that includes a structure given by a formula:

[GeRR′]ₙ. (VI)

In formula (VI), [GeRR′] is a particular type of repeat unit of the germanium-based polymer, Ge is a germanium atom, and R and R′ are substituent groups independently selected from, for example, alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups. R and R′ can be the same or can be different, and either of, or both, R and R′ can include from 1 to 20 carbon atoms. For other applications, either of, or both, R and R′ can include more than 20 carbon atoms. In formula (VI), n is a non-negative integer that is at least one and represents the number of repeat units included in the germanium-based polymer and, hence, a degree of polymerization of the germanium-based polymer. For certain applications, n is at least 10, such as at least 20, at least 50, at least 100, at least 500, at least 1,000, at least 5,000, at least 10,000, at least 50,000, at least 100,000, or at least 500,000. In some instances, n can be determined as a ratio of a molecular weight of the germanium-based polymer and a sum of atomic weights of Ge, R, and R′.

The germanium-based polymer given by formula (VI), which can sometimes be referred to as a polygermane, includes a linear backbone structure including a number of backbone atoms that are bonded to one another in a linear chain. On average, each germanium atom of the backbone structure is bonded to two substituent groups and to two other germanium atoms via germanium-germanium single bonds. In some instances, a substituent group can include a set of carbon atoms and can be bonded to a germanium atom via a carbon-germanium single bond. With proper control of processing conditions, the germanium-based polymer given by formula (VI) can be formed into products such as nanoparticles and nanostructured materials.

According to some embodiments of the invention, one method to form a germanium-based polymer involves a solution phase conversion of a set of monomers into the germanium-based polymer at high yields and at moderate temperatures and pressures. This method can be represented with reference to the formulas:

Monomers+Reducing Agent→Germanium-Based Polymer (VII)

Germanium-Based Polymer+Capping Agent→End-Capped Germanium-Based Polymer (VIII)

In formula (VII), the monomers serve as a source of germanium, and, in some instances, the monomers can also serve as a source of substituent groups of the germanium-based polymer. The monomers can include one or more types of monomers selected from, for example, RGeX₃, GeX₄, and R′R″GeX₂. R, R′, and R″ are independently selected from, for example, alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups. X is selected from, for example, halo groups, alkoxy groups, alkenoxy groups, alkynoxy groups, aryloxy groups, alkylthio groups, alkenylthio groups, alkynylthio groups, and arylthio groups.

In formula (VII), the reducing agent is selected from, for example, activated metals, such activated Group IA metals, activated Group IIA metals, and activated transition metals, and soluble salts of such activated metals with electron transfer agents, such as naphthalene, biphenyl, and anthracene. Electrochemical reduction can be used in place of, or in conjunction with, the reducing agent. Depending on the particular monomers used, the resulting germanium-based polymer is given by a formula selected from, for example, formulas (I) through (VI) discussed previously.

Desirably, the germanium-based polymer is end-capped using a capping agent in accordance with formula (VIII). The capping agent serves as a source of substituent groups for end or terminal sites of the germanium-based polymer. The capping agent can be selected from, for example, organometallic reagents of the form R′″M, where R′″ is independently selected from, for example, alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups. R, R′, R″, and R′″ can be the same or can be different, and R, R′, R″, and R′″ can each include from 1 to 20 carbon atoms. For other applications, at least one of R, R′, R″, and R′″ can include more than 20 carbon atoms. M is a metal selected from, for example, Group IA metals and Group IIA metals.

The method given by formula (VII) and (VIII) is based on a controlled chemical reduction of readily available reagents under homogeneous conditions. In some instances, various reagents can be dissolved in a reaction medium to form a reaction mixture. Typically, the reaction medium includes a solvent or a solvent mixture. Examples of solvents that can be used include a number of conventional organic solvents, such as alkanes (e.g., heptane, decane, and octadecane), arenes (e.g., benzene, chlorobenzene, dichlorobenzene, naphthalene, tetralin, toluene, xylene, and mesitylene), amines (e.g., triethylamines), ethers (e.g., glyme, diglyme, triglyme, and tetrahydrofuran), amides (e.g., dimethylformamide), and ketones (e.g., acetone and N-methylpyrrolidone). Desirably, chemical reduction is performed in an inert atmosphere, such as one including argon.

Advantageously, the method given by formula (VII) and (VIII) can produce high quality germanium-based polymers in high yield. Differentiations between the method with respect to previous attempts can sometimes include one or more of the following.

Processing conditions can be less extreme than required by previous attempts. In particular, the method can avoid high pressure and high temperature conditions as sometimes previously used that can produce large amounts of undesirable insoluble materials. Also, the method can avoid highly pyrophoric or heterogeneous conditions previously associated with use of certain types of reducing agents. In particular, the method can be used to produce germanium-based polymers under homogeneous conditions, such as associated with use of lithium naphthalide.

The resulting germanium-based polymer can be formed in higher yields than achievable with previous attempts. In some instances, the yields can be up to about 95%.

The resulting germanium-based polymer can be formed with higher molecular weights than achievable with previous attempts.

The control over a type of backbone structure or a type of substituent group for the resulting germanium-based polymer is greater than previous attempts. In turn, such control allows greater control over properties of the germanium-based polymer, such as physical, chemical, optical, and electrical properties.

The resulting germanium-based polymer can be formed with a higher proportion of germanium atoms with respect to substituent groups, such as in the form of neo-germanium atoms.

Products Formed from Germanium-Based Polymers

As discussed previously, germanium-based polymers according to some embodiments of the invention can be readily processed to form a number of products including germanium, such as coatings, clusters, nanoparticles, and nanostructured materials. In turn, these products can be used or incorporated in a number of devices, such as photovoltaic devices, thermophotovoltaic devices, photoconductors, photodetectors, photonic devices, memory cells, sensors, lasers, displays, light emitting diodes, and lighting devices.

### Formation of Nanoparticles

An example of a product that can be formed from germanium-based polymers is a nanoparticle. For some embodiments of the invention, quantum-confined nanoparticles are desirable, since these nanoparticles have properties that can be engineered by exploiting quantum confinement effects. In some instances, properties of nanoparticles can be engineered by, for example, controlling sizes of the nanoparticles, controlling shapes of the nanoparticles, controlling materials forming cores of the nanoparticles, controlling materials forming shells of the nanoparticles, controlling thickness of the shells of the nanoparticles, controlling interface regions of the nanoparticles, controlling surface ligands of the nanoparticles, controlling properties of a matrix in which the nanoparticles are dispersed, or a combination thereof. Advantageously, nanostructured materials can be formed from such quantum-confined nanoparticles, such that engineerable properties associated with quantum confinement are substantially retained.

Nanoparticles formed using indirect bandgap materials, such as Group IV semiconductor materials, are desirable for a number of applications. According to some embodiments of the invention, Group IV semiconductor materials are desirable, since their chemical, optical, electronic, and physical properties make them particularly suitable for solar applications of photovoltaic devices. These properties can be engineered by exploiting quantum confinement effects, such as by controlling sizes of nanoparticles of Group IV semiconductor materials. In particular, these properties can sometimes resemble those of a wider bandgap semiconductor material. In some instances, elemental Group IV semiconductor materials, such as silicon and germanium, are particularly desirable to mitigate impact of non-stoichiometry and defects.

The bandgap energy of bulk crystalline germanium is 0.67 eV, which allow a significant portion of a solar spectrum to be absorbed by germanium in bulk form or as quantum-confined nanoparticles. For a quantum-confined nanoparticle, its light absorption edge is typically related to its bandgap energy, which, in turn, can be determined by a size of the nanoparticle. As the size of the nanoparticle decreases, the bandgap energy typically increases. Thus, as the size of the nanoparticle decreases, the light absorption edge typically increases to higher energies or shorter wavelengths. For example, nanoparticles of germanium can have a bandgap energy of about 1 eV at a size of about 6 nm and a bandgap energy of about 1.5 eV at a size just below about 4 nm. Since the Bohr exciton of germanium is relatively large (˜12 nm), quantum confinement effects can become relevant at sizes of about 12 nm diameter and below, thus providing a large size range over which quantum confinement effects can be exploited.

Also, germanium has above bandgap transitions that can provide relatively large absorption coefficients. In particular, the absorption coefficient of germanium in bulk form can exceed 10³-10⁴ cm⁻¹ in the ultraviolet to infrared range. Quantum confinement effects can be exploited to increase the absorption coefficient of germanium in a controllable fashion.

Also, a Group IV semiconductor material, such as germanium, is desirable, since such material typically has relatively low charge carrier recombination rates. In particular, a recombination time of germanium in bulk crystalline form can be in the microsecond or millisecond range. In contrast, recombination times of direct bandgap materials can be in the nanosecond range or less. Quantum confinement effects can be exploited to increase the recombination time of germanium in a controllable fashion. The relatively long recombination times of germanium can serve to mitigate charge carrier recombination at surfaces or boundaries of a nanostructured material included in a photovoltaic device. Advantageously, the relatively long recombination time of germanium allows charge carriers to be transported across the nanostructured material and to reach electrodes before recombining. In conjunction with its relatively low charge carrier recombination rates, germanium typically has a relatively high electrical conductivity, as evidenced, for example, by a relatively high charge carrier mobility. This relatively high charge carrier mobility renders germanium desirable in a number of electronic applications. Quantum confinement effects can be exploited to increase the charge carrier mobility of germanium in a controllable fashion.

According to some embodiments of the invention, nanoparticles of germanium can be formed in accordance with a precursor approach. This precursor approach can represent an optimal approach for chemical synthesis of nanoparticles at moderate temperatures and pressures. In some instances, a precursor can refer to a reagent including most or all components to be included in a resulting product and that can be converted into that product. Desirably, a precursor should satisfy certain requirements, such as providing desired stoichiometry, desired homogeneity, desirable solubility, and desired stability. A precursor should also provide a high conversion yield into a resulting product with desired properties and using inexpensive and non-toxic starting materials. Advantageously, germanium-based polymers described herein can be used as precursors for forming nanoparticles of germanium.

In accordance with the precursor approach, one method to form nanoparticles of germanium involves a solution phase conversion of a set of germanium-based polymers into the nanoparticles under moderate conditions of temperature and pressure. In some instances, the set of germanium-based polymers can be dispersed or dissolved in a solvent or solvent mixture to form a precursor mixture. It is also contemplated that the solvent or solvent mixture can be omitted for certain applications. Examples of solvents that can be used include a number of conventional organic solvents, such as alkanes (e.g., heptane, decane, and octadecane), arenes (e.g., benzene, chlorobenzene, dichlorobenzene, naphthalene, tetralin, toluene, xylene, and mesitylene), amines (e.g., triethylamines), ethers (e.g., glyme, diglyme, triglyme, and tetrahydrofuran), amides (e.g., dimethylformamide), and ketones (e.g., acetone, 2-butanone, and cyclohexanone). In some instances, coordinating organic solvents, such as those including oxygen, nitrogen, sulfur, or phosphorus, can be desirable to produce monodisperse nanoparticles of greater sizes. High solubility of the set of germanium-based polymers can allow the precursor mixture to include a concentration of the set of germanium-based polymers that is greater than 0.1% by weight, such as from about 1% to about 30% by weight or from about 1% to about 50% by weight. For certain applications, the precursor mixture can desirably include a concentration of the set of germanium-based polymers that is from about 5% to about 25% by weight.

Next, the precursor mixture can be pyrolyzed or thermolyzed to form the nanoparticles, which can be in the form of a cluster. In particular, removal of substituent groups of the set of germanium-based polymers can lead to the formation of germanium-germanium bonds in place of germanium-carbon bonds. In such manner, the set of germanium-based polymers is converted into nanoparticles of germanium. Properties of the set of germanium-based polymers, such as backbone structure, molecular weight, and composition, can affect properties of the resulting nanoparticles. Processing conditions and reagents used to form the set of germanium-based polymers can be selected to provide properties that are desirable for a particular application of the nanoparticles. For example, a physical dimension of the backbone structure can affect the size of the nanoparticles. In addition, a time duration of thermolysis, a temperature of thermolysis, a time-temperature profile of thermolysis, concentration of the set of germanium-based polymers in the precursor mixture, type of substituent groups, and ratio of the number of substituent groups to the number of germanium atoms can determine the extent of merging of germanium and, hence, the size of the nanoparticles. For longer time durations or higher temperatures, a greater extent of merging can occur, and the set of set of germanium-based polymers can be eventually converted to bulk germanium.

In some instances, thermolysis of a precursor mixture occurs with heating, such as in an autoclave or a pressure reactor, at temperatures in the range of about 100° C. to about 700° C., such as from about 200° C. to about 600° C. For example, polygermynes can be used as precursors for forming nanoparticles of germanium. Polygermynes can thermolyze cleanly in certain organic solvents to give high yields of individual nanoparticles in an inert atmosphere. In particular, thermolysis of the polygermanes can be performed in an inert organic solvent, such as heptane, in a sealed pressure reactor (e.g., Parr instruments) for a particular time duration (e.g., a few hours). At lower temperatures, substituent groups can be initially removed from the polygermynes, and amorphous nanoparticles of germanium can then be formed. Next, at higher temperatures above, crystalline nanoparticles of germanium can be formed.

Without wishing to be bound by a particular theory, it is believed that substituent groups of a polygermyne are thermodynamically unstable with respect to germanium, and germanium-carbon bonds associated with the substituent groups have a tendency to undergo thermal scission to form a diamond-like structure. Typically, the polygermyne can decompose thermally to germanium in an inert atmosphere. Thermolysis of the polygermyne in the inert atmosphere can lead to a dark shiny material in the form of powdered germanium. In some instances, the inert atmosphere is desirably a reducing hydrogen atmosphere, such as one with a concentration of hydrogen in the range of about 4% to about 100% (by molar ratio). Since germanium typically does not form a stable carbide, resulting products in the presence of hydrogen can include germanium and low molecular weight volatile organic materials. The polygermyne can sometimes be unstable with respect to oxidative decomposition to germanium oxide, so thermolysis is desirably performed in a reducing atmosphere that is substantially devoid of oxygen and water. Oxygen and water can be reactive with the polygermyne at elevated temperatures to form a transparent or white material in the form of powdered germanium oxide (i.e., germania). The reducing atmosphere can serve to prevent or reduce the formation of germania coatings or other oxide coatings on nanoparticles of germanium. In addition, hydrogen can serve to reduce any germania to germanium. As discussed above, the reducing atmosphere can be further advantageous in aiding the removal of the substituent groups from the polygermyne. As the temperature is raised, the substituent groups of the polygermyne can react with hydrogen to form lower molecular weight molecules, such as lower alkanes. At lower temperatures (e.g., below about 400° C.) or for shorter time durations (e.g., less than about one hour), thermal decomposition of the polygermyne can lead to crosslinking between individual molecules and then conversion into amorphous nanoparticles of germanium. Higher temperatures (e.g., at or above about 400° C.) or longer time durations (e.g., one hour or more) can lead to crystallization of the nanoparticles. Typically, the crystallization temperature of the nanoparticles can be lower than that of bulk germanium. At still higher temperatures (e.g., at or above 500° C.) or longer time durations (e.g., an additional 15 minutes), the nanoparticles can merge to form larger nanoparticles.

Conversion of a polygermyne to nanoparticles of germanium can be carried out in separates steps. Thermal conversion of the polygermyne to amorphous germanium can occur in an initial step and at lower temperatures (e.g., below about 400° C.) to ensure that the nanoparticles have relatively small sizes (e.g., less than about 4 nm). Thermal conversion of the amorphous germanium to crystalline germanium can occur in a subsequent step and at higher temperatures (e.g., at or above about 500° C.). To control a size range of the nanoparticles, crystallization of the nanoparticles can occur under elevated pressures (e.g., at or above 1.5 or 2 atmospheres). Pressurization can be further advantageous in aiding crystallization of the nanoparticles at reduced temperatures. At such elevated temperatures, the nanoparticles of germanium can merge and become enlarged by a process referred to as Ostwald ripening. Smaller nanoparticles can be more reactive and lower melting than larger nanoparticles, and nanoparticles that are in contact can grow together into a large sized nanoparticle.

A composition of resulting nanoparticles can be modified by dopants, such as boron, aluminum, antimony, erbium, and phosphorus. Typically, such dopants can be used in concentrations below about 1% in terms of atomic composition. For example, boron and antimony can be added in the form of organic reagents during thermolysis of a polygermyne. Other dopants, such as erbium, can also be added in a similar manner. To reduce volatilization, dopants can be incorporated into the polygermyne itself during formation of the polygermyne.

Thermolysis of germanium-based polymers in flowing inert or reducing gas can be investigated using Thermo Gravimetric Analysis (“TGA”). The resulting product can be characterized by TGA as well as by other techniques, such as X-ray Diffraction (“XRD”), Fourier Transform Infrared (“FTIR”) Spectroscopy, Raman Spectroscopy, Chemical Analysis, Energy Dispersive Spectroscopy (“EDS”) Scanning Electron Microscopy (“SEM”), and Transmission Electron Microscopy (“TEM”).

Advantageously, the precursor approach can produce high quality monodisperse nanoparticles of germanium in high yield. Differentiations between the precursor approach with respect to previous attempts can sometimes include one or more of the following.

Processing conditions can be less extreme than required by previous attempts. In particular, the precursor approach can avoid high pressure and high temperature conditions as sometimes previously used that can produce large amounts of undesirable insoluble materials. In particular, the precursor approach can avoid arduous procedures previously associated with the use of highly pyrophoric and air-sensitive reagents, such as Group IV Zintl compounds or sodium metal.

The control of size or distribution of sizes that can be achieved for the resulting nanoparticles is greater than previous attempts. For example, a nanoparticle of germanium can have a size between about 1 nm and about 100 nm, such as between about 1 nm and about 50 nm or between about 1 nm and about 20 nm.

The resulting nanoparticles can be more stable than those formed from previous attempts. In some instances, stability of the nanoparticles can be enhanced by forming shells or ligand layers on the nanoparticles. Techniques for forming shells or ligand layers include those described in, for example, in the patent of Lee et al., U.S. Pat. No. 6,794,265, entitled “Methods of Forming Quantum Dots of Group IV Semiconductor Materials” and issued on Sep. 21, 2004, the disclosure of which is incorporated herein by reference in its entirety.

The resulting nanoparticles can be more crystalline and can have lesser defects than those formed from previous attempts. For example, a nanoparticle of germanium can be substantially crystalline and substantially defect free. Use of nanoparticles of germaniums that are substantially defect free can be desirable, since defects can reduce photoluminescence quantum efficiency and can serve as recombination sites or trapping sites for photoexcited charge carriers.

The resulting nanoparticles can be formed in higher yields than achievable with previous attempts.

### Formation of Nanostructured Materials

Another example of a product that can be formed from germanium-based polymers is a nanostructured material. Properties of a nanostructured material can be engineered for a desired level of performance for a number of applications. According to some embodiments of the invention, the configuration of nanostructured materials can cover a wide range of material morphologies that differ in their degree of contiguousness or connectivity. Within this range of material morphologies, a set of nano-networks can be used to promote a number of desirable properties. For example, a nanostructured material can include a set of nano-networks, and at least a portion of the set of nano-networks can have a contiguous configuration. In some instances, a set of nanoparticles that form a nano-network can be fused or interconnected. Advantageously, such a nano-network provides contiguous conductive paths, which allow effective charge carrier transport without relying on less effective transport mechanisms, such as a hopping or tunneling mechanism. At the same time, the degree of fusion or interconnection of the nanoparticles can be adjusted, such that engineerable properties associated with quantum confinement are substantially retained. Within this range of material morphologies, any number of nano-networks can be interdispersed, interpenetrated, fused, interconnected, or layered to at least some degree with any number of other nano-networks. In general, various nano-networks of a nanostructured material can be formed from the same material or from different materials.

According to some embodiments of the invention, a nanostructured material can be ultrafine grained with a high proportion of atoms at surfaces and interfaces. Surface and interfacial properties of a nanostructured material can sometimes have a significant impact on properties of the nanostructured material with respect to those of a bulk material.

Nanostructured materials according to various embodiments of the invention can be formed as films having a number of configurations, such as:
1. A nanostructured material can be formed as a film of a single material, such as a single component film, and can include a single nano-network.
2. A nanostructured material can be formed as a film of a single material, such as a single component film, and can include multiple nano-networks. In this case, the nano-networks can differ in their configurations or morphologies, differ in sizes of their respective nanoparticles, or differ in their doping. The nano-networks can be interdispersed, interpenetrating, fused, interconnected, or layered with one another. For example, the nano-networks can be formed from nanoparticles of different sizes, can be arranged in different material morphologies, can be doped differently, or a combination thereof. In particular, the nano-networks can be formed from nanoparticles of germanium and can differ in their doping. Boundaries between the nano-networks can form homojunctions that allow effective charge separation.
3. A nanostructured material can be formed as a film of multiple materials, such as a multi-component film, and can include multiple nano-networks. In this case, the nano-networks can differ in their materials, differ in their configurations or morphologies, differ in sizes of their respective nanoparticles, or differ in their doping. The nano-networks can be interdispersed, interpenetrating, fused, interconnected, or layered with one another. For example, the nano-networks can be formed from nanoparticles of germanium and nanoparticles of silicon that can have different sizes, that can be arranged in different material morphologies, that can be doped differently, or a combination thereof. Boundaries between the nano-networks can form homojunctions that allow effective charge separation.
4. A nanostructured material can be formed as a film of a single material, such as a single component film, and can include nanoparticles that are fused completely to “full density.”
5. A nanostructured material can be formed as a film of multiple materials, such as a multi-component film, and can include nanoparticles that are fused completely to “full density.”
6. A nanostructured material can be formed as a film including a single layer of nanoparticles.
7. A nanostructured material can be formed as a combination of the above, such as a film including multiple layers of one or more of the above categories. For example, a nanostructured material can be formed as a film that includes multiple layers of category 3 discussed above. In this case, boundaries between the layers can form heterojunctions that allow effective charge separation.

Nanostructured materials formed using indirect bandgap materials, such as Group IV semiconductor materials, are desirable for a number of applications. For example, nanoparticles of germanium can be used either alone or in combination with other types of nanoparticles to form interdispersed, interpenetrating, fused, interconnected, or layered nano-networks of a nanostructured material, which can serve as a photoactive material that is included in a photovoltaic device. As discussed previously, Group IV semiconductor materials are desirable, since their chemical, optical, electronic, and physical properties make them particularly suitable for solar applications of photovoltaic devices. These properties can be engineered by exploiting quantum confinement effects, such as by controlling sizes of nanoparticles of Group IV semiconductor materials.

According to some embodiments of the invention, nanostructured materials of germanium can be formed in accordance with a precursor approach. This precursor approach can represent an optimal approach for chemical synthesis of nanostructured materials at moderate temperatures and pressures. Advantageously, germanium-based polymers described herein can be used as precursors for forming nanostructured materials of germanium.

In accordance with the precursor approach, one method to form a nanostructured material of germanium involves a solid phase conversion of a set of germanium-based polymers into the nanoparticles under moderate conditions of temperature and pressure. In some instances, the set of germanium-based polymers can be dispersed or dissolved in a solvent or solvent mixture to form a precursor mixture. It is also contemplated that the solvent or solvent mixture can be omitted for certain applications. Examples of solvents that can be used include a number of conventional organic solvents, such as alkanes (e.g., heptane, decane, and octadecane), arenes (e.g., benzene, tetralin, toluene, xylene, and mesitylene), amines (e.g., triethylamines), ethers (e.g., glyme, diglyme, triglyme, and tetrahydrofuran), amides (e.g., dimethylformamide), and ketones (e.g., acetone, 2-butanone, and cyclohexanone). In some instances, coordinating organic solvents, such as those including oxygen, nitrogen, sulfur, or phosphorus, can be desirable to produce monodisperse nanoparticles of greater sizes. High solubility of the set of germanium-based polymers can allow the precursor mixture to include a concentration of the set of germanium-based polymers that is greater than 0.1% by weight, such as from about 1% to about 30% by weight or from about 1% to about 50% by weight. For certain applications, the precursor mixture can desirably include a concentration of the set of germanium-based polymers that is from about 5% to about 25% by weight. In some instances, coordinating organic solvents, such as those including oxygen, nitrogen, sulfur, or phosphorus, can be desirable to produce monodisperse nanoparticles of greater sizes.

Next, the precursor mixture can be applied to a substrate to form a coating. Examples of substrates that can be used include those formed using silicon, silica, aluminum, alumina, magnesium, transition metal oxides, and metals, such as titanium, tungsten, steel, tungsten, chromium, iron, zirconium, and other transition and lanthanide metals. High solubility of the set of germanium-based polymers can allow the precursor mixture to be readily foamed into the coating using a number of techniques, such as spray coating, spin coating, dip coating, meniscus coating, and casting. For certain applications, the precursor mixture can be applied in a pattern using a selective printing process, such as screen printing, offset printing, or gravure printing. A number of additives used in coating technology can be used to facilitate formation of the coating with desired properties, such as homogeneity and smoothness. In some instances, the solvent or solvent mixture can be removed from the coating by, for example, evaporation or soft bake.

Once formed, the coating can be pyrolyzed or thermolyzed to form the nanostructured material, which can be in the form of a film. As discussed previously, removal of substituent groups of the set of germanium-based polymers can lead to the formation of germanium-germanium bonds in place of germanium-carbon bonds. In such manner, the set of germanium-based polymers can be converted into the nanostructured material. Properties of the set of germanium-based polymers, such as backbone structure, molecular weight, and composition, can affect properties of the resulting nanostructured material. As further discussed below, processing conditions and reagents used to form the set of germanium-based polymers can be selected to provide properties that are desirable for a particular application of the nanostructured material. For example, a physical dimension of the backbone structure can affect the size of nanoparticles included in the nanostructured material. In addition, a time duration of thermolysis, a temperature of thermolysis, a time-temperature profile of thermolysis, concentration of the set of germanium-based polymers in the precursor mixture, type of substituent groups, and ratio of the number of substituent groups to the number of germanium atoms can determine the extent of merging of germanium and, hence, the size of the nanoparticles, the degree of connectivity of the nanoparticles, and the porosity of the nanostructured material. For longer time durations or higher temperatures, a greater extent of merging can occur, and the nanostructured material can have a greater degree of connectivity and lower porosity.

In some instances, thermolysis of a coating occurs with heating, such as in an autoclave or a pressure reactor, at temperatures in the range of about 100° C. to about 700° C., such as from about 200° C. to about 600° C. For example, polygermynes can be used as precursors for forming a nanostructured material of germanium. Polygermynes can thermolyze cleanly in an inert atmosphere of a sealed pressure reactor (e.g., Parr instruments) for a particular time duration (e.g., a few hours). At lower temperatures, substituent groups can be initially removed from the polygermynes, and amorphous nanoparticles of germanium can then be formed. Next, at higher temperatures, crystalline nanoparticles of germanium can be formed. At still higher temperatures, the crystalline nanoparticles can become fused or interconnected to form the nanostructured material.

As discussed previously, thermolysis of a polygermyne is typically performed in an inert atmosphere, which is desirably a reducing hydrogen atmosphere. Conversion of the polygermyne to a nanostructured material of germanium can be carried out in separates steps. Thermal conversion of the polygermyne to amorphous germanium can occur in an initial step and at lower temperatures (e.g., below about 400° C.) to ensure that the nanoparticles have relatively small sizes (e.g., less than about 3 nm or about 4 nm). Thermal conversion of the amorphous germanium to crystalline germanium can occur in a subsequent step and at higher temperatures (e.g., at or above about 500° C.). To control a size range of the nanoparticles, crystallization of the nanoparticles can occur under elevated pressures (e.g., at or above 1.5 or 2 atmospheres). Pressurization can be further advantageous in aiding crystallization of the nanoparticles at reduced temperatures. At such elevated temperatures, the nanoparticles of germanium can become fused or interconnected. Smaller nanoparticles can be more reactive and lower melting than larger nanoparticles, and nanoparticles that are in contact can become fused or interconnected to form a nano-network. In some instances, fusion can form a neck connecting individual nanoparticles, and a minimum diameter of the neck can be controlled so as to be smaller than sizes of the individual nanoparticles. Control over the minimum diameter of the neck can serve to provide mechanical joining between the individual nanoparticles while retaining size dependent properties associated with quantum confinement. The neck can perturb resulting properties to be between those of an individual nanoparticle, which can exhibit size dependent properties along three orthogonal dimensions, and those associated with quantum confinement along two orthogonal dimensions. The resulting nanostructured material can be highly regular in terms of sizes of nanoparticles, porosity, and material morphology. Without wishing to be bound by a particular theory, it is believed that formation of the nanostructured material can involve a spinodal decomposition process or a diffusion limited aggregation of smaller nanoparticles.

A composition of resulting nanostructured material can be modified by dopants, such as boron, aluminum, antimony, erbium, and phosphorus. Typically, such dopants can be used in concentrations below about 1% in terms of atomic composition. For example, boron and antimony can be added in the form of organic reagents during thermolysis of a polygermyne. Other dopants, such as erbium, can also be added in a similar manner. To reduce volatilization, dopants can be incorporated into the polygermyne itself during formation of the polygermyne.

Thermolysis of germanium-based polymers in flowing inert or reducing gas can be investigated using TGA. The resulting product can be characterized by TGA as well as by other techniques, such as XRD, FTIR Spectroscopy, Raman Spectroscopy, Secondary Ion Mass Spectrometry (“SIMS”), Chemical Analysis, Optical Profilometry, Resistivity Measurements, Hall Measurements, EDS, SEM, and TEM.

Advantageously, the precursor approach can produce high quality films of germanium in high yield. Typical film thickness can range from about 10 nm to greater than about 1 μm. Multiple coatings of a precursor mixture can be applied to a substrate to increase film thickness. Desirably, each coating can be thermolyzed before applying a next coating. In some instances, a next coating can serve to penetrate a previously formed porous film to reduce its porosity while retaining individuals nanoparticles included in that film. It is also contemplated that multiple coatings can differ in their doping or can differ in properties of their respective germanium-based polymers. It is further contemplated that the multiple coatings can be subjected to different thermolysis conditions so as to provide different properties, such as bandgaps or crystallinity.

Differentiations between the precursor approach with respect to previous attempts can sometimes include one or more of the following.

The precursor approach provides a facile and inexpensive route to forming films of germanium without requiring vacuum systems. Such facile and inexpensive route is based at least in part on the enhanced film forming ability of a germanium-based polymer, which can depend on, for example, a high molecular weight of the germanium-based polymer, a highly branched configuration of the germanium-based polymer, a match between solubility properties of the germanium-based polymer and a coating solvent or solvent mixture, and a similar surface tension between the germanium-based polymer and the coating solvent or solvent mixture to provide smooth surfaces upon drying.

The resulting films can be highly smooth with a roughness less than about 0.5 nm or about 1 nm in terms of rms as measured by Optical Profilometry. In some instances, a surface of the film can be highly uniform with open pores between interconnected nanoparticles.

The resulting films can be highly electrically conductive. A higher electrical conductivity can be associated with a lower porosity. Resistivity measurements can be performed on the films, both amorphous and crystalline, by a four-point probe method and by parallel deposited electrodes. In some instances, amorphous films can have resistivities in the range of about 1×10³ ohm-cm to about 2×10³ ohm-cm, while crystalline films can have resistivities in the range of about 1×10⁻¹ ohm-cm to about 1×10³ ohm-cm. The films can be doped to increase electrical conductivity. Hull measurements can also be performed on the films to determine carrier mobilities. In some instances, carrier mobilities can be in the range of about 2 to about 200 cm²V⁻¹ s⁻¹ with charge carriers being primarily holes in accordance with p doping.

The resulting film can have enhanced mechanical integrity.

The control of over porosity, connectivity, bandgap, crystallinity, and associated electrical and optical properties that can be achieved for the resulting films is greater than previous attempts. For example, the porosity of the films can be controlled by selection of a polygermyne, a coating solvent or solvent system, thickness of coating, and time-temperature profile of thermolysis. In particular, the porosity of the films can be readily controlled to be in the range of about 10% to about 90%, depending on the specific application. In some instances, the resulting films can be highly porous (e.g., >80% porosity) and include nanoparticles loosely interconnected to form a nano-network. A degree of porosity can be measured as a volume percent of open space in the films, as determined by, for example, SEM or TEM. By proper selection of reagents and processing conditions, lower porosity films (e.g., <20% porosity) can be formed while still retaining individual nanoparticles, which can be either amorphous or crystalline.

The resulting films can have a high surface area to volume ratio. A higher surface area to volume ratio can be associated with a higher porosity. For certain applications, films with a higher porosity can be chemically modified to reduce their tendency to absorb oxygen, water, or organic molecules from normal air environment.

The composition of the resulting films can be substantially germanium with oxygen and carbon present in less than about 0.1 percent in terms of atomic composition. Other elements, such as phosphors or sodium, can also be present in lower amounts.

### EXAMPLES

The following examples describe specific aspects of some embodiments of the invention to illustrate and provide a description for those of ordinary skill in the art. The examples should not be construed as limiting the invention, as the examples merely provide specific methodology useful in understanding and practicing some embodiments of the invention.

### Example 1

### Formation of Germanium-Based Polymer

A 1000-ml three-neck round bottom flask equipped with a stirring bar, a reflux condenser, and a thermometer was purged with argon and charged with a reducing agent and 400 ml of a selected reaction medium (e.g., a solvent such as THF). The reducing agent included small pieces of a selected alkali metal (e.g., lithium, 2.5 grams, 360 mmol) and a selected electron transfer agent (e.g., naphthalene, 46.1 grams, 360 mmol). The resulting dark green reaction mixture was stirred at ambient temperature for a period of time (e.g., between about 2 and 100 hours) and then cooled to lower temperatures (e.g., between about −78° C. and 20° C.). A source of germanium, namely freshly distilled RGeX₃ (120 mmol, X═Cl), was added dropwise over a period of time (e.g., between about 5 and 100 minutes), and the resulting dark red reaction mixture was stirred at higher temperatures (e.g., between about −78° C. and 100° C.) for a period of time (e.g., between about 2 and 100 hours). The reaction mixture was treated with a selected capping agent (36 mmol), which was added dropwise to keep the temperature below 30° C. After the reaction mixture was stirred at ambient temperature for a period of time (e.g., between about 2 and 48 hours), it was quenched with degassed dilute protic acid (pH˜2). The solvent was removed under reduced pressure at ambient temperature. The resulting germanium-based polymer, which was in the form of a yellow to black solid, was filtered off and washed with water and a copious amount of methanol. The germanium-based polymer was dissolved in a solvent (e.g., THF) and reprecipitated with a nonsolvent (e.g., methanol). After filtration or centrifugation, the germanium-based polymer was collected and dried in a vacuum oven.

### Example 2

### Formation of Germanium-Based Polymer

Example 1 is repeated using a 50%/50% mixture (by molar ratio) of RGeCl₃ and GeCl₄ as the source of germanium.

### Example 3

### Formation of Germanium-Based Polymer

Example 1 is repeated using a 75%/25% mixture (by molar ratio) of RGeCl₃ and GeCl₄ as the source of germanium.

### Example 4

### Formation of Germanium-Based Polymer

Example 1 is repeated using a 90/%10% mixture (by molar ratio) of RGeCl₃ and GeCl₄ as the source of germanium.

### Example 5

### Formation of Germanium-Based Polymer

Example 1 is repeated using a 50%/50% mixture (by molar ratio) of R₂GeCl₂ and RGeCl₃ as the source of germanium.

### Example 6

### Formation of Germanium-Based Polymer

Example 1 is repeated using a 50%/50% mixture (by molar ratio) of R₂GeCl₂ and GeCl₄ as the source of germanium.

### Example 7

### Formation of Germanium-Based Polymer

Example 1 is repeated using a 20%/30%/50% mixture (by molar ratio) of R₂GeCl₂, RGeCl₃, and GeCl₄ as the source of germanium.

### Example 8

### Formation of Germanium-Based Polymer

Example 1 is repeated using a 50%/50% mixture (by molar ratio) of RGeCl₃ and R′GeCl₃ as the source of germanium, where R and R′ are different groups.

### Example 9

### Formation of Germanium-Based Polymer

Example 1 is repeated using sodium naphthalide as the reducing agent.

### Example 10

### Formation of Germanium-Based Polymer

Example 1 is repeated using sodium metal as the reducing agent.

### Example 11

### Formation of Germanium-Based Polymer

Example 1 is repeated using lithium metal as the reducing agent.

### Example 12

### Formation of Germanium-Based Polymer

Example 1 is repeated using 4,4′-Di-tert-butylbiphenyl as the electron transfer agent.

### Example 13

### Formation of Germanium-Based Polymer

Example 1 is repeated using allylmagnesium bromide as the capping agent.

### Example 14

### Formation of Germanium-Based Polymer

Example 1 is repeated using phenyllithium as the capping agent.

### Example 15

### Formation of Germanium-Based Polymer

Example 1 is repeated using glyme as the reaction medium.

### Example 16

### Formation of Precursor Mixture from Germanium-Based Polymer

A typical precursor mixture was formed by dissolving about 5 to 30 grams of a germanium-based polymer (e.g. a polygermyne) in a powdered form in 100 grams of a solvent or a solvent mixture. Dopants of boron and antimony can be introduced by adding decaborane and Sb(N(CH₃)₂)₃, respectively, to the precursor mixture in a concentration range from a few parts per million (“ppm”) to a few percent (by molar ratio or by weight).

### Example 17

### Formation of Nanostructured Material from Precursor Mixture

A nanostructured material was formed from a precursor mixture that included 12% by weight of a polygermyne in a powdered form. In particular, a few drops of the precursor mixture was spread on a surface of a substrate, which was placed on a vacuum chuck equipped with a commercial spin coater. The substrate was spun at 1,000 revolution per minute (“rpm”) for 30 seconds and then at 3,000 rpm for 1 minute in a glovebox with reduced oxygen and moisture levels (e.g., less than 1 ppm of oxygen).

To reduce oxidative degradation, the resulting coating was sintered shortly thereafter. An example of a sintering recipe using a NEYTECH vacuum furnace is set forth below:

GAS: ON

VACUUM: ON

RAMP RATE: 10° C./minute

TEMPERATURE: 200° C.

HOLD: 0.1 hour

RAMP RATE: 10° C./minute

TEMPERATURE: 400° C.

HOLD: 1 hour

RAMP RATE: 25° C./minute

TEMPERATURE: 50° C.

GAS: OFF

VACUUM: OFF

END

The coating was held briefly at 200° C. to dry off solvent. At 400° C., thermolysis took place, and carbonaceous material from the polygermyne was drawn out, yielding an amorphous germanium-based film. Next, crystallization of germanium occurred to form a film with controlled porosity and morphology and with 100 nm nominal thickness.

### Example 18

### Formation of Nanostructured Material from Precursor Mixture

A nanostructured material was formed from a precursor mixture that included polygermyne and a relatively small amount of Sb(N(CH₃)₂)₃. In particular, the precursor mixture was spread on a surface of a substrate, which was placed on a vacuum chuck equipped with a commercial spin coater. The substrate was spun in a glovebox with reduced oxygen and moisture levels (e.g., less than 1 ppm of oxygen).

To reduce oxidative degradation, the resulting coating was sintered shortly thereafter. An example of a sintering recipe using a NEYTECH vacuum furnace is set forth below:

FORMING GAS (4%): ON

VACUUM: ON

RAMP RATE: 10° C./minute

TEMPERATURE: 200° C.

HOLD: 0.1 hour

RAMP RATE: 10° C./minute

TEMPERATURE: 350° C.

HOLD: 5 hour

RAMP RATE: 100° C./minute

TEMPERATURE: 550° C.

HOLD: 1 hour

RAMP RATE: 100° C./minute

TEMPERATURE: 50° C.

FORMING GAS: OFF

VACUUM OFF

END

The coating was held briefly at 200° C. to dry off solvent. At 350° C., thermolysis took place, and carbonaceous material from the polygermyne and Sb(N(CH₃)₂)₃ was drawn out, yielding an amorphous germanium-based film. Next, crystallization of germanium occurred to form a film with controlled porosity and morphology. Due to the presence of antimony, crystallization of germanium occurred at higher temperatures, namely at 550° C. Compared with the absence of doping, the film had a band gap that increased from 1.0 electron volt (“eV”) on average to 1.3±0.1 eV. In addition, the film had a different morphology and included quantum dots of smaller sizes.

### Example 19

### Characterization of Nano Structured Material

By adjusting thermolysis conditions, a number of properties of a resulting nanostructured material can be tailored for a particular application of the nanostructured material. In particular, by adjusting a sintering temperature, it was demonstrated that properties such as crystallinity, electrical conductivity, carbon content, porosity, weight loss, current-voltage characteristics, and band gap can be adjusted to desired levels.

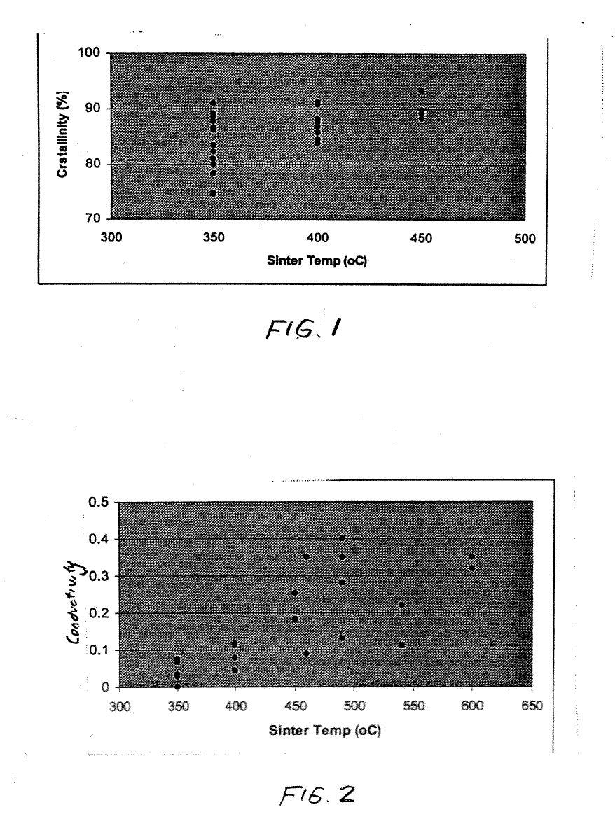

FIG. 1 plots crystallinity of a nanostructured material as a function of sintering temperature, according to an embodiment of the invention. Thermolysis of a coating formed from a polygermyne leads to the loss of carbonaceous material as organic side chains leave the polygermyne, yielding an amorphous germanium-based film. Further heating leads to a film with a desired level of crystallinity.

FIG. 2 plots electrical conductivity of a nanostructured material as a function of sintering temperature, according to an embodiment of the invention. As illustrated in FIG. 2, the electrical conductivity generally increases as carbonaceous material is drawn out and as crystallinity increases. Addition of a small amount of antimony can lead to a decrease in electrical conductivity of a nanostructured material. For example, electrical conductivity of a nanostructured material formed from a precursor mixture including about 1% by weight of Sb(N(CH₃)₂)₃ was determined to be about 10⁻⁵ S/cm, while electrical conductivity of a nanostructured material formed in the absence of antimony was determined to be about 10⁻¹ S/cm.

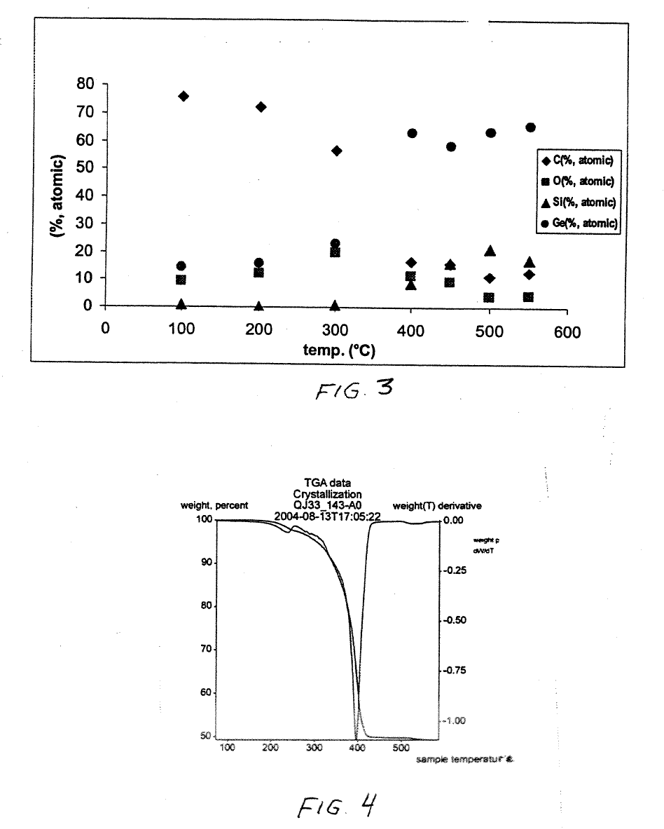

FIG. 3 plots elemental composition of a nanostructured material (as measured by EDS) as a function of sintering temperature, according to an embodiment of the invention. A coating formed from poly(butylgermyne) was applied to a glass substrate and then sintered to form a film on the glass substrate. As illustrated in FIG. 3, carbon content of the nanostructured material generally decreases as the sintering temperature increases, while germanium content of the nanostructured material generally increases as the sintering temperature increases. It is believed that oxygen content and silicon content that were measured are from the glass substrate. Electron microscopy images of the nanostructured material are obtained as a function of sintering temperature. Based on these images, porosity of the nanostructured material was observed to generally increase as the sintering temperature increases. It is believed that this increase in porosity is a result of nanoparticle growth.

FIG. 4 plots weight loss of a nanostructured material (as measured by TGA) as a function of sintering temperature, according to an embodiment of the invention. As illustrated in FIG. 4, an onset of weight loss starts at about 250° C. when a coating formed from a polygermyne is heated in argon or in argon with hydrogen, and a completion of weight loss occurs at about 400° C. Here, the weight loss is believed to result from alkyl groups leaving the polygermyne. Elemental composition of the resulting film can be determined from chemical elemental analysis to be substantially germanium. The chemical elemental analysis can also be confirmed by EDS.

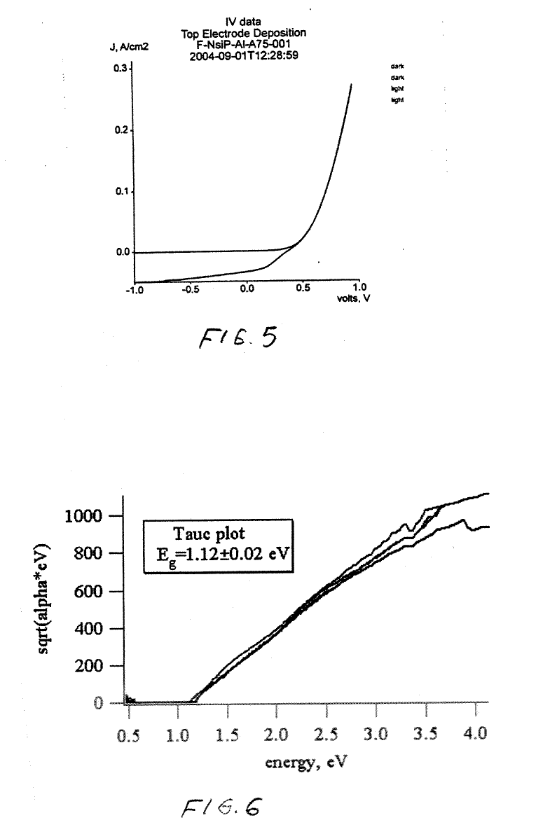

FIG. 5 illustrates current-voltage characteristics of a nanostructured material in the dark and under illumination, according to an embodiment of the invention. A coating formed from a polygermyne was applied to a silicon substrate and then sintered to form a film on the silicon substrate. As illustrated in FIG. 5, the current-voltage characteristics of the film substantially conform with the expected behavior for a silicon-germanium heterojunction. As such, the film can be used to form a heterojunction that is used in photovoltaic devices for solar energy conversion.

FIG. 6 provides a Tauc plot for a nanostructured material, according to an embodiment of the invention. As one of ordinary skill in the art will understand, a Tauc plot is a plot of a square root of an optical density of a material as a function of optical energy. The intercept of the resulting curve with respect to the optical energy axis typically corresponds to a bandgap of the material. The bandgap can be an indirect bandgap, if any, or a direct bandgap. As illustrated in FIG. 6, the nanostructured material has a band gap of 1.12 eV, as compared with bulk germanium that has a bandgap of 0.67 eV. Here, this increase in bandgap is believed to result from quantum confinement effects.

It should be recognized that the embodiments of the invention described above are provided by way of example, and various other embodiments of the invention are contemplated. For example, another embodiment of the invention relates to a photo-selective method of forming germania patterned films. In particular, a polygermyne can be photo-reactive and can form germania when irradiated in the presence of oxygen. Thus, irradiation through a photo mask can lead to the formation of insoluble germania in irradiated areas, while the polygermyne in non-irradiated areas can remain soluble and can be readily removed by solvent rinsing.

As another example, another embodiment of the invention relates to germanium-silicon alloys that can have a number of desirable properties, such as for electronic and photonic applications in the integrated circuit industry. In particular, it is contemplated that a polygermyne and a polysilyne can be used to form such germanium-silicon alloys. The polysilyne can be formed in a similar fashion as described herein, such as by chemical reduction of alkylsilicon halides. Both the polygermyne and the polysilyne can be highly soluble in organic solvents to form a precursor mixture. The precursor mixture can be applied to a substrate and can be pyrolyzed or thermolyzed in a reducing atmosphere to form a germanium-silicon alloy in the form of a film.

A practitioner of ordinary skill in the art requires no additional explanation in developing the germanium-based polymers, the nanoparticles, and the nanostructured materials described herein but may nevertheless find some helpful guidance by examining the patent of Lee et al., U.S. Pat. No. 6,819,845, entitled “Optical Devices with Engineered Nonlinear Nanocomposite Materials” and issued on Nov. 16, 2004; the patent of Lee et al., U.S. Pat. No. 6,794,265, entitled “Methods of Forming Quantum Dots of Group IV Semiconductor Materials” and issued on Sep. 21, 2004; and the patent of Lee et al., U.S. Pat. No. 6,710,366, entitled “Nanocomposite Materials with Engineered Properties” and issued on Mar. 23, 2004; the disclosures of which are incorporated herein by reference in their entireties. A practitioner of ordinary skill in the art may also find some helpful guidance by examining the patent application of Lee, U.S. patent application Ser. No. 10/212,001 (U.S. Patent Application Publication No. 2003/0066998), entitled “Quantum Dots of Group IV Semiconductor Materials” and filed on Aug. 2, 2002; and the patent of Lee et al., U.S. Pat. No. 7,005,669, entitled “Quantum Dots, Nanocomposite Materials with Quantum Dots, Devices with Quantum Dots, and Related Fabrication Methods” and issued on Feb. 28, 2006; the disclosures of which are incorporated herein by reference in their entireties.

While the invention has been described with reference to the specific embodiments thereof, it should be understood by those skilled in the art that various changes may be made and equivalents may be substituted without departing from the true spirit and scope of the invention as defined by the appended claims. In addition, many modifications may be made to adapt a particular situation, material, composition of matter, method, or process to the objective, spirit and scope of the invention. All such modifications are intended to be within the scope of the claims appended hereto. In particular, while the methods disclosed herein have been described with reference to particular operations performed in a particular order, it will be understood that these operations, may be combined, sub-divided, or re-ordered to form an equivalent method without departing from the teachings of the invention. Accordingly, unless specifically indicated herein, the order and grouping of the operations are not limitations of the invention.

What is claimed is:

1. A method of forming nanoparticles of germanium, comprising:
dispersing a germanium-based polymer in a solvent to form a precursor mixture, the germanium-based polymer including a repeat unit given by the formula: [GeR], wherein Ge is a germanium atom, and R is a substituent group that includes from 1 to 20 carbon atoms; and
thermolyzing the precursor mixture to form nanoparticles of germanium having sizes in the range of 1 nm to 100 nm.

2. The method of claim 1, wherein the precursor mixture includes from 1 percent to 50 percent by weight of the germanium-based polymer.

3. The method of claim 1, wherein the precursor mixture includes from 5 percent to 25 percent by weight of the germanium-based polymer.

4. The method of claim 1, wherein the solvent is selected from alkanes, arenes, amines, ethers, amides, and ketones.

5. The method of claim 1, wherein the solvent is a coordinating organic solvent.

6. The method of claim 1, wherein the germanium-based polymer has a molecular weight that is at least 15,000 daltons.

7. The method of claim 1, wherein the germanium-based polymer has a molecular weight that is at least 50,000 daltons.

8. The method of claim 1, wherein R is selected from lower alkyl groups, lower alkenyl groups, lower alkynyl groups, lower aryl groups, and lower iminyl groups.

9. The method of claim 1, wherein the repeat unit is a first repeat unit, R is a first substituent group, and the germanium-based polymer includes a second repeat unit given by the formula: [GeR′], wherein R′ is a second substituent group that includes from 1 to 20 carbon atoms, and R and R′ are different.

10. The method of claim 1, wherein the repeat unit is a first repeat unit, and the germanium-based polymer includes a second repeat unit given by the formula: [Ge].

11. The method of claim 1, wherein the repeat unit is a first repeat unit, R is a first substituent group, and the germanium-based polymer includes a second repeat unit given by the formula: [GeR′R″], wherein R′ and R″ are a second substituent group and a third substituent group, respectively, and R′ and R″ each includes from 1 to 20 carbon atoms.

12. The method of claim 1, wherein thermolyzing the precursor mixture is performed at a temperature in the range of 200° C. to 600° C.

13. The method of claim 1, wherein thermolyzing the precursor mixture is performed in a reducing atmosphere.

14. The method of claim 1, wherein thermolyzing the precursor mixture is performed at a pressure that is at least 2 atmospheres.

15. The method of claim 1, wherein the nanoparticles of germanium are monodispersed with respect to their sizes.

16. The method of claim 1 wherein the nanoparticles of germanium are substantially crystalline and substantially defect free.

17. A method of forming nanoparticles of germanium, comprising:
providing a germanium-based polymer including a network backbone structure and substituent groups that are bonded to the network backbone structure, the network backbone structure including germanium atoms that are bonded to one another; and
heating the germanium-based polymer to remove the substituent groups, such that nanoparticles of germanium having sizes in the nm range are formed.

18. The method of claim 17, wherein the germanium-based polymer is given by the formula:
[GeR]ₙ,
wherein n is a non-negative integer that is at least 20, Ge is a germanium atom, and R is selected from alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups.

19. The method of claim 17, wherein the germanium-based polymer is given by the formula:
[GeR]ₙ[GeR′]ₘ,
wherein n and m are non-negative integers having a sum that is at least 20, Ge is a germanium atom, and R and R′ are independently selected from alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups. N-substituted amino groups, alkylcarbonylamino groups, N-substituted alkylcarbonylamino groups, alkenylcarbonylamino groups. N-substituted alkenylcarbonylamino groups, alkynylcarbonylamino groups, N-substituted alkynylcarbonylamino groups, arylcarbonylamino groups. N-substituted arylcarbonylamino groups, silyl groups, and siloxy groups.

20. The method of claim 17, wherein the germanium-based polymer is given by the formula:
[GeR]ₙ[Ge]ₘ,
wherein n and m are non-negative integers having a sum that is at least 20, Ge is a germanium atom, and R is selected from alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups.

21. The method of claim 17, wherein the germanium-based polymer is given by the formula:
[GeR]ₙ[GeR′R″]ₘ,
wherein n and m are non-negative integers having a sum that is at least 20, Ge is a germanium atom, and R, R′, and R″ are independently selected from alkyl groups, alkenyl groups, alkynyl groups, aryl groups, iminyl groups, alkoxy groups, alkenoxy groups, alkynoxy groups, aryloxy groups, carboxy groups, alkylcarbonyloxy groups, alkenylcarbonyloxy groups, alkynylcarbonyloxy groups, arylcarbonyloxy groups, alkylthio groups, alkenylthio groups, alkynylthio groups, arylthio groups, cyano groups, N-substituted amino groups, alkylcarbonylamino groups. N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, silyl groups, and siloxy groups.

22. The method of claim 17, further comprising:
dissolving the germanium-based polymer in a solvent to form a precursor mixture that includes from 1 percent to 50 percent by weight of the germanium-based polymer,
wherein heating the germanium-based polymer is performed by heating the precursor mixture.

23. The method of claim 22, wherein heating the precursor mixture is performed in a reducing atmosphere.

24. The method of claim 22, wherein heating the precursor mixture is performed in accordance with a time-temperature profile, such that the nanoparticles of germanium have sizes in the range of 1 nm to 50 nm.

25. The method of claim 24, wherein heating the precursor mixture in accordance with the time-temperature profile includes:
maintaining the precursor mixture at a first temperature for a first time duration; and
maintaining the precursor mixture at a second temperature for a second time duration, the second temperature being higher than the first temperature.

26. The method of claim 25, wherein the first temperature is below 400° C., and the second temperature is at least 400° C.

27. The method of claim 17, wherein the nanoparticles of germanium have a density of defects that is less than 1 defect per 1000 nanoparticles of germanium.

28. The method of claim 27, wherein the density of defects is less than 1 defect per 10⁶ nanoparticles of germanium.

29. The method of claim 17, wherein the nanoparticles of germanium have a photoluminescence quantum efficiency that is at least 10 percent.

30. The method of claim 29, wherein the photoluminescence quantum efficiency is at least 20 percent.

31. A method of forming a nanostructured material, comprising:
dissolving a polygermyne in an organic solvent to form a precursor mixture that includes from 1 percent to 50 percent by weight of the polygermyne;
applying the precursor mixture to a substrate to form a coating; and
thermolyzing the coating in accordance with a time-temperature profile to form a nanostructured material having a porosity in the range of 10 percent to 90 percent.

32. The method of claim 31, wherein the polygermyne has a molecular weight that is at least 15,000 daltons.

33. The method of claim 31, wherein the polygermyne includes substituent groups to enhance solubility of the polygermyne in the organic solvent.

34. The method of claim 31, wherein the time-temperature profile specifies a first temperature for a first time duration and a second temperature for a second time duration, the second temperature being higher than the first temperature.

35. The method of claim 34, wherein the first temperature is below 400° C., and the second temperature is at least 500° C.

36. The method of claim 31, wherein thermolyzing the coating is performed at a pressure that is at least 2 atmospheres.
